(19) United States
(12) Patent Application Publication
(10) Pub. No.: US 2020/0273940 A1
(43) Pub. Date: Aug. 27, 2020

(54) ORGANIC LIGHT EMITTING DIODE DISPLAY DEVICE

(71) Applicant: Samsung Display Co., LTD., Yongin-si (KR)

(72) Inventors: Minwoo BYUN, Seongnam-si (KR); Kwang-Min KIM, Seoul (KR); Kiwook KIM, Hwaseong-si (KR); Jisu NA, Yongin-si (KR); Yangwan KIM, Hwaseong-si (KR)

(73) Assignee: Samsung Display Co., LTD., Yongin-si (KR)

(21) Appl. No.: 16/709,277

(22) Filed: Dec. 10, 2019

(30) Foreign Application Priority Data
Feb. 25, 2019 (KR) 10-2019-0021747

(51) Int. Cl. H01L 27/32; H01L 51/52; G09G 3/3225

(52) U.S. Cl. CPC H01L 27/3276; H01L 27/326; G09G 2300/0426; H01L 51/5253; G09G 3/3225; H01L 27/3258

(57) ABSTRACT

An organic light emitting diode (OLED) display device includes a substrate, a light emitting layer, first and second power supply wires, a connection pattern, and an upper electrode. The substrate has display, peripheral and pad regions. The peripheral region includes first, second and third peripheral regions. The first power supply wire is disposed in the second and third peripheral regions and a part of the first peripheral region. The second power supply wire is disposed in the display region and first and third peripheral regions. The connection pattern overlaps and electrically connects to the first power supply wire. The upper electrode is electrically connected to the connection pattern, disposed in the display region and a part of the peripheral region over the connection pattern and the light emitting layer, and partially overlapped with the first power supply wire and the connection pattern.

### CROSS-REFERENCE TO RELATED APPLICATION

This application claims priority under 35 USC § 119 to Korean Patent Application No. 10-2019-0021747, filed on Feb. 25, 2019 in the Korean Intellectual Property Office (KIPO), the entire disclosure of which is incorporated herein by reference.

### BACKGROUND

### 1. Field

The disclosure relates generally to an organic light emitting diode (OLED) display device, and more specifically, to a power supply configuration therefor that minimizes opportunity for defects including short-circuiting and damage to others of the display device components that may result from heat that is generated by the power supply.

### 2. Description of the Related Art

Flat panel display devices, such as liquid crystal displays and OLED displays are now preferred over cathode ray tube display device since they are lightweight and thin in profile.

Generally, an OLED display device may include a display region, a peripheral region surrounding the display region, and a pad region disposed in one side of the peripheral region. Pixel circuits and organic light emitting diodes may be disposed in the display region, along with first and second power supply wires. Pad electrodes may be disposed in the pad region. For example, a low power supply voltage and a high power supply voltage may be generated from an external device, and the voltages may be provided to the first and second power supply wires through the pad electrodes, respectively. The low power supply voltage applied to the first power supply wire may be provided to a cathode electrode of the organic light emitting diode, and the high power supply voltage applied to the second power supply wire may be provided to an anode electrode of the organic light emitting diode. As such, the first and second power supply wires are disposed together in the peripheral region, so that a width of the first power supply wire may be relatively small. When the OLED display is driven at a high luminance, a current may be concentrated on the first power supply wire disposed in a peripheral region, which is adjacent to a display area and a pad region, thereby causing the temperature in one or more of the peripheral region and the pad region to become excessive. When the temperature becomes excessive, the first power supply wire may be short-circuited or an insulating layer disposed around the first power supply wire may be deformed due to the heat excess.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments herein are directed to a power supply configuration for an OLED display that minimizes opportunity for defects including short-circuiting and damage to others of the display components which may result from heat that is generated by the power supply.

An OLED display device according to an exemplary embodiment includes a substrate, a light emitting layer, a first power supply wire, a second power supply wire, a connection pattern, and an upper electrode. The substrate has a display region, a peripheral region surrounding the display region and including first, second, and third peripheral regions, and a pad region disposed in a side of the peripheral region. The light emitting layer is disposed in the display region. The first power supply wire is disposed in the second and third peripheral regions and a part of the first peripheral region. The second power supply wire is disposed in the display region, the first peripheral region, and the third peripheral region, and outside of the second peripheral region. The connection pattern is disposed to overlap with the first power supply wire in the second and third peripheral regions, and is electrically connected to the first power supply wire. The upper electrode is disposed in the display region and a part of the peripheral region over the connection pattern and the light emitting layer, and is overlapped with the first power supply wire and the connection pattern. The upper electrode is electrically connected to the connection pattern.

The organic light emitting diode display device may further include pad electrodes disposed in a first part of the pad region. The first peripheral region is disposed adjacent to the first part of the pad region, and the second peripheral region may be disposed at sides of the first peripheral region, and adjacent to a second part of the pad region where no pad electrode is disposed.

The first power supply wire may be electrically connected to the pad electrodes.

The first power supply wire may be electrically connected with at least two of the pad electrodes, and the second power supply wire may be electrically connected with at least one of the pad electrodes, and the at least one of the pad electrodes connected with the second power supply wire may be disposed inward of the at least two of the pad electrodes connected with the first power supply wire.

The connection pattern may be disposed outside of the first peripheral region.

A low power supply voltage may be applied to the first power supply wire, and a high power supply voltage may be applied to the second power supply wire.

The second power supply wire may include a first portion disposed in the first peripheral region, a second portion disposed in the display region and having a lattice shape, and a third portion disposed in a part of the third peripheral region to surround the second portion. The first, second, and third portions of the second power supply wire may be formed integrally with each other.

The first and second portions of the second power supply wire may be connected to each other in a part of the first peripheral region that is adjacent to a boundary between the display region and the peripheral region, and the second and third portions of the second power supply wire may be connected to each other in a part of the third peripheral region that is adjacent to the boundary between the display region and the peripheral region.

The third portion of the second power supply wire may be spaced apart from an inner side of the first power supply wire in the third peripheral region.

The third portion of the second power supply wire may be disposed outside of the second peripheral region.

The display region may have a rectangular shape with curved corners when viewed in a plan view. The corners of the display region may include first curve corners disposed adjacent to the pad region and second curved corners facing the first curved corners.

The first curved corners may be disposed adjacent to the second peripheral region, and the second curved corners may be disposed adjacent to the third peripheral region.

The first power supply wire may have a first width in the second peripheral region, and may have a second width, which is less than the first width, in the third peripheral region.

The connection pattern may have a width corresponding to each of the first width and the second width of the first power supply wire.

The organic light emitting diode display device may further include a protective insulating layer, a first planarization layer, and a second planarization layer. The protective insulating layer may be disposed in the display region and the peripheral region and between the substrate and the light emitting layer, and may have an opening in the second peripheral region. The first planarization layer may be disposed in the display region and a part of the peripheral region, and on the protective insulating layer to expose the opening of the protective insulating layer. The second planarization layer may be disposed in the display region and a part of the peripheral region, and on the first planarization layer, and may have an opening for exposing the first power supply wire in the second peripheral region.

The light emitting layer may extend from the display region to the peripheral region, and the light emitting layer is disposed in the peripheral region to not overlap with the opening of the second planarization layer.

The organic light emitting diode display device may further include a lower electrode disposed in the display region, and on the second planarization layer. The upper electrode may be disposed on the lower electrode, and to extend from the display region to the peripheral region.

The upper electrode may directly contact the connection pattern in the second peripheral region.

The lower electrode and the connection pattern may be disposed on a same layer.

The first power supply wire may include a first sub-power supply wire and a second sub-power supply wire. The first sub-power supply wire may be disposed between the substrate and the protective insulating layer, and may be exposed by the opening of the protective insulating layer. The second sub-power supply wire may be disposed between the first planarization layer and the second planarization layer, and may directly contact the first sub-power supply wire through the opening of the protective insulating layer. The second sub-power supply wire may be exposed by the opening of the second planarization layer.

The connection pattern may directly contact the second sub-power supply wire through the opening of the second planarization layer.

The organic light emitting diode display device may further include a semiconductor element disposed in the display region, and between the substrate and the protective insulating layer, and a wire pattern and a connection electrode disposed in the display region, and between the first planarization layer and the second planarization layer.

The wire pattern, the connection electrode, and the second sub-power supply wire may be disposed on a same layer.

The semiconductor elements may include an active layer disposed in the display region a gate insulating layer disposed on the active layer, a gate electrode disposed on the gate insulating layer, an insulating interlayer disposed on the gate electrode, and source and drain electrodes disposed on the insulating interlayer.

The source and drain electrodes and the first sub-power supply wire may be disposed on a same layer.

Since the OLED display device according to exemplary embodiments includes the first power supply wire and the connection pattern having a relatively wide width, an amount of heat generated by the first power supply wire disposed in the first peripheral region and the second peripheral region may be relatively reduced.

The OLED display device includes both the first power supply wire and the connection pattern having a relatively wide width, such that the connection pattern may make direct contact with the first power supply wire in the second peripheral region through provided openings in the second planarization layer. As a result, an amount of the heat generated in the first power supply wire may be further reduced. Accordingly, the OLED display device may prevent defect which might otherwise occur due to generation of an excessive amount of heat.

### BRIEF DESCRIPTION OF THE DRAWINGS

An additional appreciation according to the embodiments of the invention will become more apparent by describing in detail the embodiments thereof with reference to the accompanying drawings, wherein:

FIG. 1 is a plan view illustrating an OLED display device according to exemplary embodiments of the invention;

FIG. 2 is a plan view illustrating first and second power supply wires included in the OLED display device of FIG. 1;

FIG. 3A is a plan view illustrating a connection pattern disposed on the first power supply wire of FIG. 2;

FIG. 3B is a plan view illustrating a conventional OLED display device;

FIG. 4 is a block diagram illustrating an external device that may be electrically connected to the OLED display device of FIG. 1;

FIG. 5 is a circuit diagram showing a sub-pixel circuit disposed in the sub-pixel circuit region of FIG. 1, and an OLED disposed on the sub-pixel circuit;

FIG. 6A is a sectional view taken along line I-I′ of FIG. 3A;

FIG. 6B is a plan view illustrating a light emitting layer and an upper electrode that are disposed on the connection pattern of FIG. 3A;

FIG. 6C is a partially enlarged plan view illustrating a region A of FIG. 6B; and

FIGS. 7 to 19 are views illustrating a method of manufacturing an OLED display device according to exemplary embodiments of the invention.

### DETAILED DESCRIPTION OF THE EMBODIMENTS

An additional appreciation according to the embodiments of the invention will become more apparent by describing in detail the embodiments thereof with reference to the accompanying drawings, wherein:

Although the invention may be modified in various manners and have additional embodiments, embodiments are illustrated in the accompanying drawings and will be mainly described in the specification. However, the scope of the invention is not limited to the embodiments in the accompanying drawings and the specification and should be construed as including all the changes, equivalents and substitutions included in the spirit and scope of the invention.

The drawings and description are to be regarded as only illustrative in nature, and thus are not limiting of embodiments described and claimed herein. Some of the parts which are not associated with the description may not be provided in order to describe embodiments of the invention and like reference numerals refer to like elements throughout the specification.

In the drawings, a size and thickness of each element are arbitrarily represented for better understanding and ease of description, however the invention is not limited thereto. In the drawings, the thickness of layers, films, panels, regions, and other elements may be exaggerated for clarity. In the drawings, for better understanding and ease of description, the thicknesses of some layers and areas may be exaggerated.

Further, in the specification, the phrase “in a plan view” means when an object portion is viewed from above, and the phrase “in a cross-sectional view” means when a cross-section taken by vertically cutting an object portion is viewed from the side. Additionally, the terms “overlap” or “overlapped” means that a first object may be above or below a second object, and vice versa. When a layer, film, region, substrate, or area, is referred to as being “on” another layer, film, region, substrate, or area, it may be directly on the other film, region, substrate, or area, or intervening films, regions, substrates, or areas, may be present therebetween. Conversely, when a layer, film, region, substrate, or area, is referred to as being “directly on” another layer, film, region, substrate, or area, intervening layers, films, regions, substrates, or areas, may be absent therebetween. Further when a layer, film, region, substrate, or area, is referred to as being “below” another layer, film, region, substrate, or area, it may be directly below the other layer, film, region, substrate, or area, or intervening layers, films, regions, substrates, or areas, may be present therebetween. Conversely, when a layer, film, region, substrate, or area, is referred to as being “directly below” another layer, film, region, substrate, or area, intervening layers, films, regions, substrates, or areas, may be absent therebetween. Further, “over” or “on” may include positioning on or below an object and does not necessarily imply a direction based upon gravity.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

Throughout the specification, when an element is referred to as being “connected” to another element, the element may be “directly connected” to another element, or “electrically connected” to another element with one or more intervening elements interposed therebetween. It will be further understood that when the terms “comprises,” “comprising,” “includes” and/or “including” are used in this specification, they or it may specify the presence of stated features, integers, steps, operations, elements and/or components, but do not preclude the presence or addition of other features, integers, steps, operations, elements, components, and/or any combination thereof

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

Unless otherwise defined, all terms used herein (including technical and scientific terms) have the same meaning as commonly understood by those skilled in the art to which this invention pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

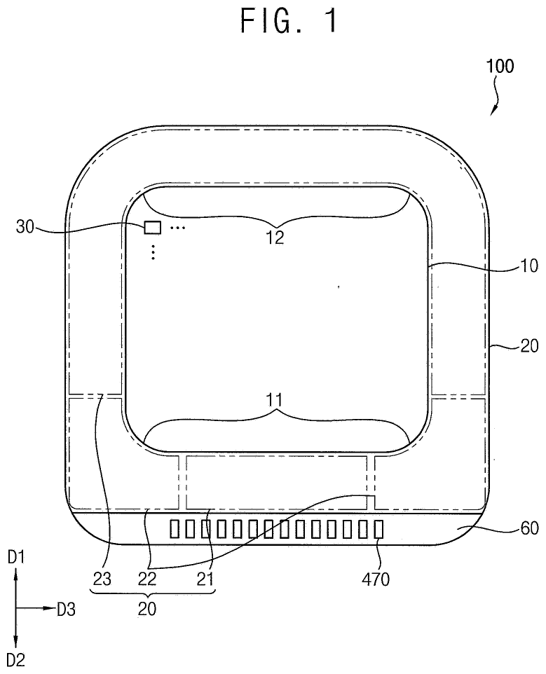

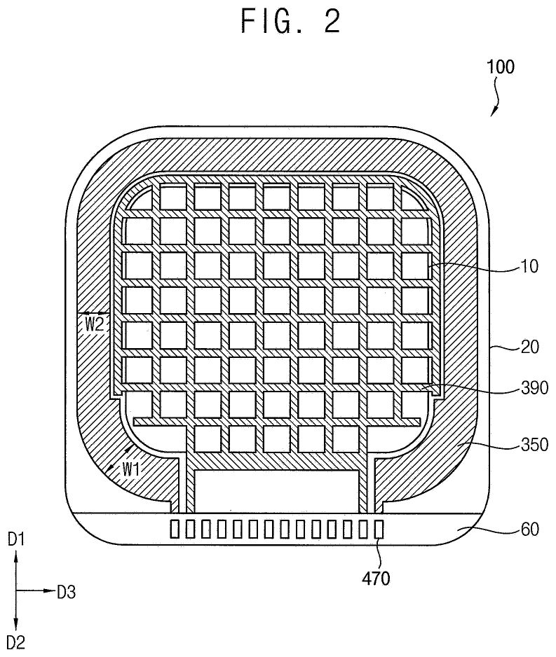

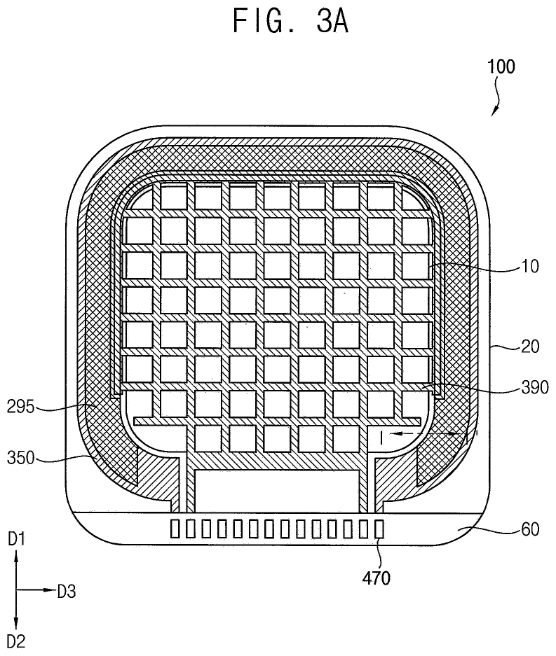

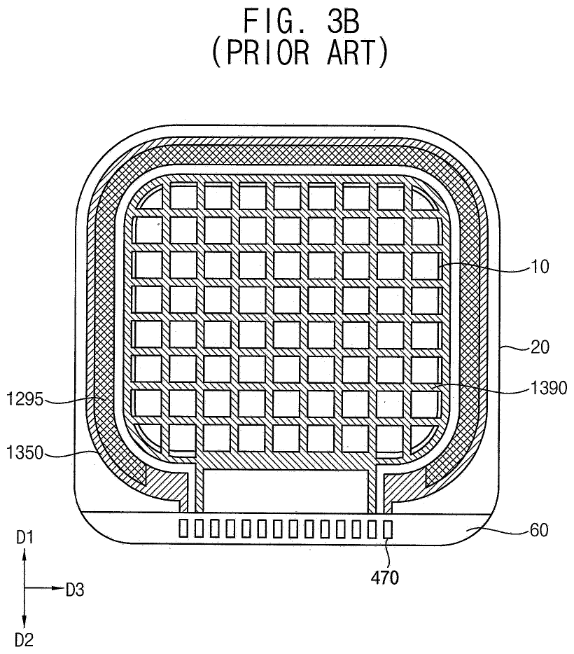

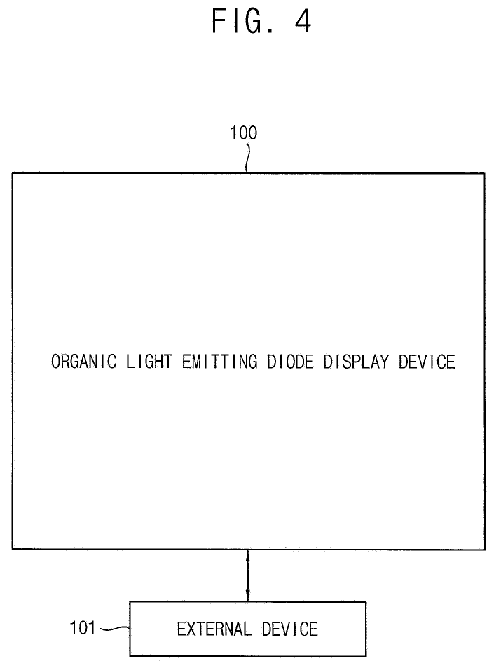

FIG. 1 is a plan view showing an organic light emitting diode (OLED) display device according to exemplary embodiments of the invention, and FIG. 2 is a plan view for explaining first and second power supply wires included in the organic light emitting diode display device of FIG. 1. FIG. 3A is a plan view for explaining a connection pattern disposed on the first power supply wire of FIG. 2, and FIG. 3B is a plan view showing a conventional OLED display device. FIG. 4 is a block diagram for explaining an external device electrically connected to the OLED display device of FIG. 1.

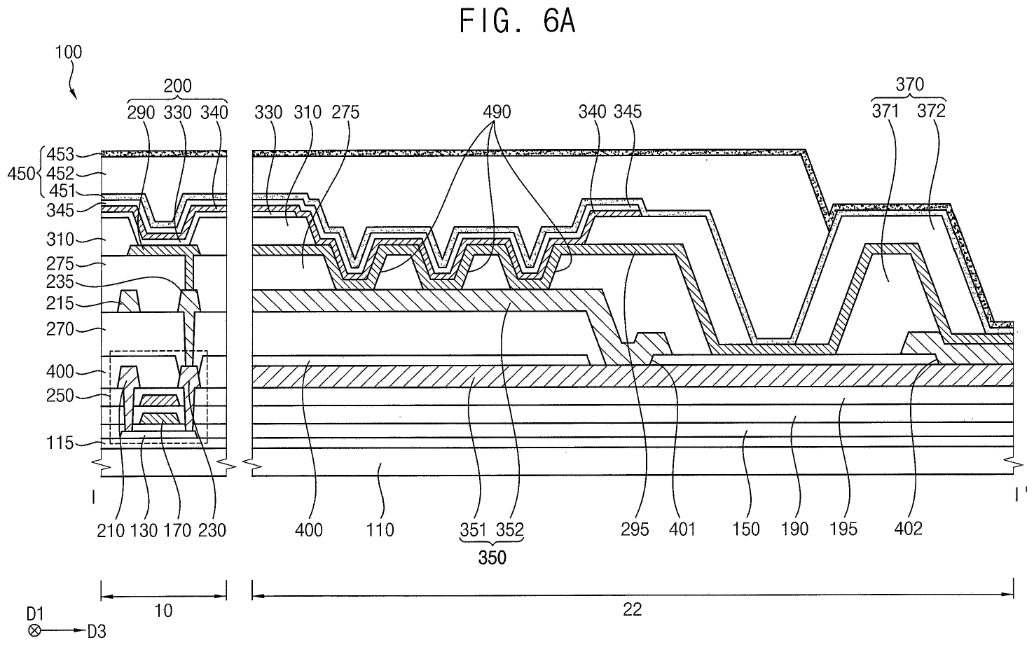

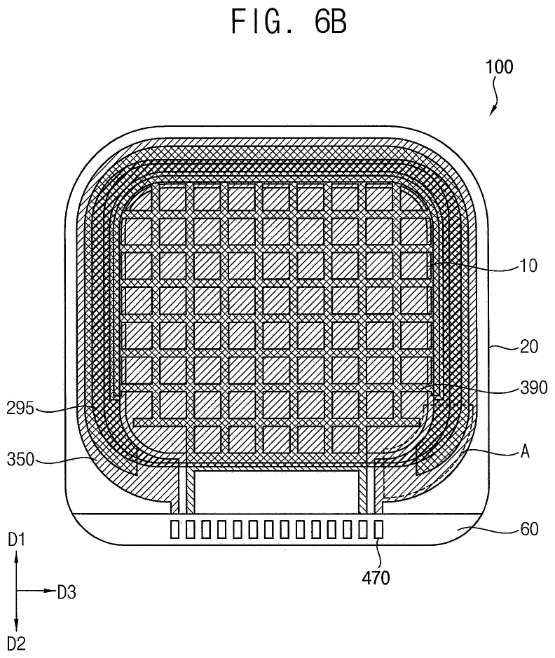

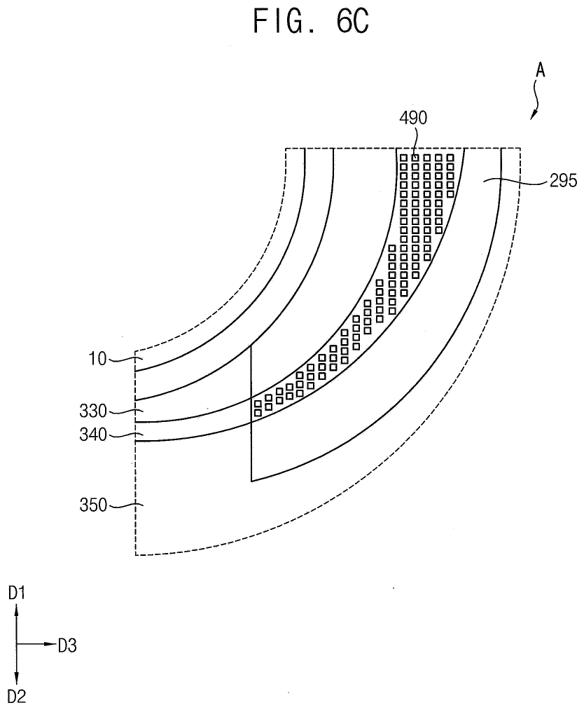

Referring to FIGS. 1, 2, 3A, and 4, an OLED display device 100 may include a first power supply wire 350, a second power supply wire 390, a connection pattern 295, pad electrodes 470, and may include a display region 10, a peripheral region 20, and a pad region 60. In this case, the peripheral region 20 may substantially surround a periphery of the display region 10, and the pad region 60 may be disposed in a side of the peripheral region 20. The display region 10 may include sub-pixel circuit regions 30. In exemplary embodiments, the display region 10 may have a rectangular shape with curved corners when viewed in a plan view, and the OLED display device 100 (or substrate 110 of FIG. 6A) may also have a rectangular shape with curved corners when viewed in a plan view. For example, the display region 10 may include first corners 11 disposed adjacent the pad region 60 and second corners 12 facing the first corners 11.

The peripheral region 20 may include a first peripheral region 21, a second peripheral region 22, and a third peripheral region 23. For example, the first peripheral region 21 of the peripheral region 20 may be adjacent to the pad electrodes 470 disposed in the pad region 60, so as to correspond to a first part of the pad region 60 where the pad electrodes 470 are disposed. The second peripheral region 22 may be disposed at each of sides of the first peripheral region 21, so as to be at both lower side ends of the peripheral region 20. As such, the second peripheral region 22 may be a region that is outside of, i.e., separate from, the first peripheral region 21. The third peripheral region 23 may correspond to a remaining part of the peripheral region 20 excluding the first peripheral region 21 and the second peripheral region 22.

Furthermore, the second peripheral region 22 may correspond to a second part of the pad region 60 where no pad electrodes 470 is disposed. In this case, the second part of the pad region 60 may be disposed at each of sides of the first part of the pad region 60 in which the pad electrodes 470 are disposed. As such, the second peripheral region 22 is thus also outside of the pad region 60. The second peripheral region 22 may be disposed adjacent to the first corners 11 of the display region 10. In other words, the first peripheral region 21, the second peripheral region 22, and the third peripheral region 23 may be different from each other, and may not be overlapped with each other. In exemplary embodiments, the second peripheral region 22 may not be overlapped with the pad electrodes 470 in a longitudinal direction (e.g., first direction D1 or second direction D2 opposite to first direction D1) in the plan view of the OLED display device 100, and may be disposed at both lower side ends of the peripheral region 20. For example, the peripheral region 20 may have a track shape with a hollow center when viewed in the plan view.

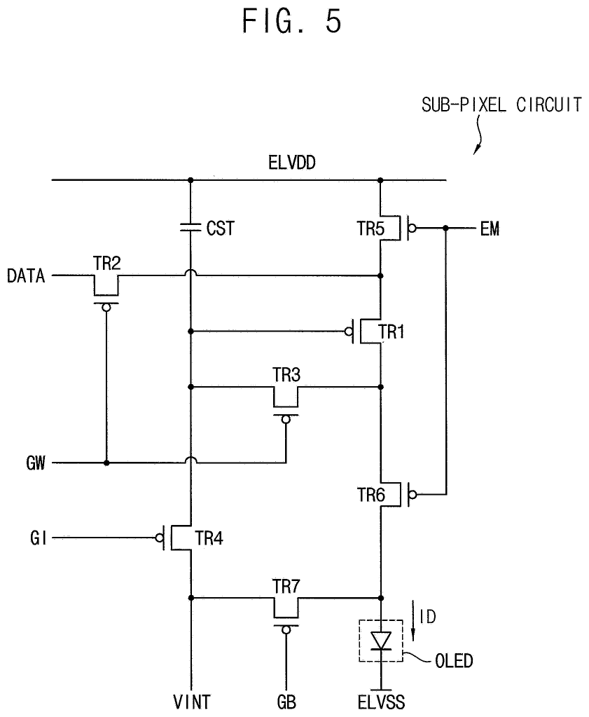

The sub-pixel circuit regions 30 may be arranged on the display region 10. For example, a sub-pixel circuit SPC of FIG. 5 (e.g., semiconductor element 250 of FIG. 6A) may be disposed in each of the sub-pixel circuit regions 30, and an organic light emitting diode OLED (e.g., sub-pixel structure 200 of FIG. 6A) may be disposed on the sub-pixel circuit SPC. An image may be displayed on the display region 10 through the sub-pixel circuit SPC and the OLED.

For example, first, second, and third sub-pixel circuits may be disposed in the sub-pixel circuit regions 30. The first sub-pixel circuit may be connected to a first organic light emitting diode for emitting red light, the second sub-pixel circuit may be connected to a second organic light emitting diode for emitting green light, and the third sub-pixel circuit may be connected to a third organic light emitting diode for emitting blue light.

In exemplary embodiments, the first organic light emitting diode may be overlapped with the first sub-pixel circuit, the second organic light emitting diode may be overlapped with the second sub-pixel circuit, and the third organic light emitting diode may be overlapped with the third sub-pixel circuit. As another example, the first organic light emitting diode may be overlapped with a part of the first sub-pixel circuit and a part of other sub-pixel circuits different from the first sub-pixel circuit, the second organic light emitting diode may be overlapped with a part of the second sub-pixel circuit and a part of other sub-pixel circuits different from the second sub-pixel circuit, and the third organic light emitting diode may be overlapped with a part of the third sub-pixel circuit and a part of other sub-pixel circuits different from the third sub-pixel circuit. For example, the first to third organic light emitting diodes may be arranged by using an RGB stripe scheme in which rectangles having an identical size are arranged in order, an S-stripe scheme including a blue organic light emitting diode having a relatively large area, a WRGB scheme further including a white organic light emitting diode, a PenTile scheme in which RG-GB patterns are repeatedly arranged, etc.

At least one driving transistor, at least one switching transistor, at least one capacitor, and the like may be disposed in each of the sub-pixel circuit regions 30. In exemplary embodiments, one driving transistor (e.g., first transistor TR1 of FIG. 5) and six switching transistors (e.g., second to seventh transistors TR2, TR3, TR4, TRS, TR6, and TR7 of FIG. 5), one storage capacitor (e.g., storage capacitor CST of FIG. 5), and the like may be disposed in each of the sub-pixel circuit regions 30.

Although the OLED display device 100 of the invention has been described as having a track shape when viewed from the top, the shape is not limited thereto. For example, the OLED display device 100 may have a rectangular shape, a triangular shape, a rhombic shape, a polygonal shape, a circular shape, or an elliptical shape when viewed from the top.

Wires may be disposed in the peripheral region 20. For example, the wires may include a data signal wire, a gate signal wire, a light emission control signal wire, a gate initialization signal wire, an initialization voltage wire, a power supply wire, etc. The wires may extend from the peripheral region 20 to the display region 10, and may be electrically connected to the sub-pixel circuit SPC and the organic light emitting diode OLED. Furthermore, a gate driver, a data driver, and the like may be disposed in the peripheral region 20.

As shown in FIGS. 2 and 3A, the first power supply wire 350 may be disposed in a part of the peripheral region 20. In other words, the first power supply wire 350 may be disposed in the second peripheral region 22, the third peripheral region 23, and a part of the first peripheral region 21. The first power supply wire 350 may have a hook shape (e.g., a ring with a lower opening). In exemplary embodiments, the first power supply wire 350 may have a first width W1 in the second peripheral region 22, and may have a second width W2 that is less than the first width W1 in the third peripheral region 23. The first power supply wire 350 may be electrically connected to the pad electrodes 470 in the first peripheral region 21. For example, the first power supply wire 350 may be electrically connected to the outermost pad electrodes 470 in the pad region 60. A low power supply voltage may be applied to the first power supply wire 350, and the low power supply voltage may be provided to a cathode electrode (e.g., upper electrode 340 of FIG. 6A) through the connection pattern 295.

Although the first power supply wire 350 is shown as a single wire in FIG. 2, the first power supply wire 350 may be at least two wires overlapped with each other. In other words, the first power supply wire 350 may have a structure in which at least two wires are stacked (e.g., first sub-power supply wire 351 and second sub-power supply wire 352 in FIG. 6A).

The second power supply wire 390 may be disposed in the display region 10 and a part of the peripheral region 20. In other words, the second power supply wire 390 may be disposed in the display region 10, the first peripheral region 21, and a part of the third peripheral region 23. The second power supply wire 390 may be disposed between ends of the first power supply wire 350 in the first peripheral region 21, and have a lattice shape in the display region 10. The second power supply wire 390 may be spaced apart from an inner side of the first power supply wire 350 in the third peripheral region 23. In this case, a portion of the second power supply wire 390 disposed in the first peripheral region 21 is defined as a first portion, a portion of the second power supply wire 390 disposed in the display region 10 is defined as a second portion, and a portion of the second power supply wire 390 surrounding the second portion is defined as a third portion. The first, second, and third portions may be formed integrally with each other. The first and second portions of the second power supply wire 390 may be connected to each other in the first peripheral region 21 adjacent to a boundary between the display region 10 and the peripheral region 20, and the second and third portions of the second power supply wire 390 may be connected to each other in the third peripheral region 23 adjacent to the boundary between the display region 10 and the peripheral region 20. In exemplary embodiments, the third portion of the second power supply wire 390 may not be disposed in the second peripheral region 22. When referring to FIG. 2, the second portion and the third portion of the second power supply wire 390 may be disposed outside of the second peripheral region 22. Likewise, the first portion of the second power supply wire 390 may also be disposed outside of second peripheral region 22. In this way, none of any portion of the second power supply wire 390 may be contained within the second peripheral region 22. As a result, only the first power supply wire 350 may be disposed in the second peripheral region 22 and have a first width W1, which is relatively wider than the second width thereof in the third peripheral region 23. The second power supply wire 390 may be electrically connected to the pad electrodes 470 in the first peripheral region 21. For example, the second power supply wire 390 may be electrically connected to pad electrodes 470 which are within the outermost pad electrodes 470 so as to be connected, in the direction D3, inwardly of the connection of the first power supply wire 350. As such, the second power supply wire 390 is disposed outside of the second peripheral region 22 when the first portion of the second power supply wire 390 is disposed in the first peripheral region 21 and the pad region 60 to connect with pad electrodes 470 that are distal from the outermost pad electrodes 470 to which the first power supply wire 350 connects. A high power supply voltage may be applied to the second power supply wire 390, and then provided to an anode electrode (e.g., lower electrode 290 of FIG. 6A).

Although the second power supply wire 390 is shown as a single wire in FIG. 2, the second power supply wire 390 may be at least two wires overlapped with each other. In other words, the second power supply wire 390 may have a structure in which at least two wires are stacked.

The connection pattern 295 may be disposed only in the second peripheral region 22 and only in the third peripheral region 23, and be on the first power supply wire 350 in the second peripheral region 22 and the third peripheral region 23. In exemplary embodiments, therefore, the connection pattern 295 is not disposed in the first peripheral region 21. That is, the connection pattern 295 is disposed outside of the first peripheral region such that no part of the connection pattern is contained in the first peripheral region 295. The connection pattern 295 may have a shape of a ring having a lower opening. The connection pattern 295 may be overlapped with the first power supply wire 350 in the second peripheral region 22 to correspond with the first power supply wire 350. Such correspondence may include the connection pattern 295 having a width, in the second peripheral region 22, that is both less than the width W1 of the first power supply wire 350 and greater than a remaining width of the connection pattern 295 in the third peripheral region 23. The connection pattern 295 may be overlapped with the third portion of the second power supply wire 390 and the first power supply wire 350 in the third peripheral region 23. As another example, the connection pattern 295 may further correspond with the first power supply wire 350 insofar as the width of the connection pattern 295 may be equal to or greater than the width W1 of the first power supply wire 350 in the second peripheral region 22, and the connection pattern 295 may not be overlapped with the third portion of the second power supply wire 390 in the third peripheral region 23 and have a width equal to or greater than the width W2 of the first power supply wire 350. A low power supply voltage may be applied to the connection pattern 295 from the first power supply wire 350, and the low power supply voltage may then be provided to a cathode electrode (e.g., upper electrode 340 of FIG. 6A).

When referring to the conventional OLED display device shown in FIG. 3B, first and second power supply wires 1350 and 1390 may be disposed together in the peripheral region 20. In other words, a second portion of the second power supply wire 1390 may be disposed in a part of the first peripheral region 21, and, in contrast to exemplary embodiments herein, also in the second peripheral region 22. Therefore, the first power supply wire 1350 may have a relatively reduced width in the part of the first peripheral region 21 and the second peripheral region 22. In other words, the first power supply wire 1350 may have a substantially identical width (e.g., second width W2) in both the first peripheral region 21 and the second peripheral region 22 of the peripheral region 20. When this is the case and the conventional organic light emitting diode display device is driven at a high luminance, a current may be excessively concentrated on the first power supply wire 1350 disposed in the part of the first peripheral region 21 and the second peripheral region 22, thereby causing an excessive amount of heat to be generated. As such, the first power supply wire 1350 may be short-circuited, or an insulating layer disposed around the first power supply wire 1350 may be deformed because of the excessive heat. In either of these situations, the conventional OLED display device may become defective.

Yet, in exemplary embodiments of the invention, the first power supply wire 350 and the connection pattern 295 have a relatively wide width in the second peripheral region 22 As a result, heat that is generated in the first power supply wire 350 disposed in the first peripheral region 21 and the second peripheral region 22 may be relatively reduced due to, when compared to the conventional OLED display device, the increased areas of the first power supply wire 350 and the connection pattern 295. For example, heat that is generated in the first power supply wire 350 in accordance with connection to connection pattern 295 may be distributed in accordance with the width W1, in contrast to a distribution of heat in accordance with the width W2 as in the case of the conventional OLED display device.

Referring again to FIGS. 1, 2, 3A, and 4, the pad electrodes 470 electrically connected to the external device 101 may be disposed in the pad region 60. Connection electrodes may be disposed between the pad electrodes 470 and the first and second power supply wires 350 and 390. For example, the connection electrodes may electrically connect the pad electrodes 470 to each of the first and second power supply wires 350 and 390. As another example, ends of each of the first and second power supply wires 350 and 390 may be directly connected to the pad electrodes 470.

The external device 101 may be electrically connected to the OLED display device 100 through a flexible printed circuit board or a printed circuit board. For example, one side of the flexible printed circuit board may make direct contact with the pad electrodes 470, and an opposite side of the flexible printed circuit board may make direct contact with the external device 101. The external device 101 may provide a data signal, a gate signal, a light emission control signal, a gate initialization signal, an initialization voltage, a high power supply voltage, a low power supply voltage, and the like to the OLED display device 100. In exemplary embodiments, the low power supply voltage (e.g., low power supply voltage ELVSS of FIG. 5) may be generated from the external device 101, and the low power supply voltage may be provided to the first power supply wire 350 through the flexible printed circuit board, the pad electrodes 470, and the connection electrodes. The high power supply voltage (e.g., high power supply voltage ELVDD of FIG. 5) may be generated from the external device 101, and the high power supply voltage may be provided to the second power supply wire 390 through the flexible printed circuit board, the pad electrodes 470, and the connection electrodes. Furthermore, a driver integrated circuit may be mounted on the flexible printed circuit board. In exemplary embodiments, the driver integrated circuit may be mounted on the OLED display device 100 adjacent to the pad electrodes 470.

FIG. 5 is a circuit diagram showing a sub-pixel circuit disposed in the sub-pixel circuit region of FIG. 1 and an OLED disposed on the sub-pixel circuit.

Referring to FIG. 5, a sub-pixel circuit SPC and OLED (e.g., sub-pixel structure 200 of FIG. 6A) may be disposed in each of the sub-pixel circuit regions 20 of the OLED display device 100, and one sub-pixel circuit SPC may include first to seventh transistors TR1, TR2, TR3, TR4, TRS, TR6, and TR7 (e.g. semiconductor element 250 of FIG. 6A), a storage capacitor CST, a wire for a high power supply voltage ELVDD (e.g., second power supply wire 390 of FIGS. 2 and 3), a wire for a low power supply voltage ELVSS (e.g., first power supply wire 350 of FIGS. 2 and 3), a wire for an initialization voltage VINT, a wire for a data signal DATA, a wire for a gate signal GW, a wire for a gate initialization signal GI, a wire for a light emission control signal EM, a wire for a diode initialization signal GB, etc. As described above, the first transistor TR1 may correspond to a driving transistor, and the second to seventh transistors TR2, TR3, TR4, TRS, TR6, and TR7 may correspond to a switching transistor. Each of the first to seventh transistors TR1, TR2, TR3, TR4, TRS, TR6, and TR7 may include a first terminal, a second terminal, a channel, and a gate terminal. In exemplary embodiments, the first terminal may be a source terminal, and the second terminal may be a drain terminal. As another example, the first terminal may be the drain terminal, and the second terminal may be the source terminal.

The OLED may output light based on a driving current ID. The OLED may include a first terminal and a second terminal. In exemplary embodiments, the second terminal of the organic light emitting diode OLED may be supplied with the low power supply voltage ELVSS, and the first terminal of the organic light emitting diode OLED may be supplied with the high power supply voltage ELVDD. For example, the first terminal of the organic light emitting diode OLED may be an anode terminal, and the second terminal of the organic light emitting diode OLED may be a cathode terminal. As another example, the first terminal of the organic light emitting diode OLED may be the cathode terminal, and the second terminal of the organic light emitting diode OLED may be the anode terminal. In exemplary embodiments, the anode terminal of the organic light emitting diode OLED may correspond to a lower electrode 290 of FIG. 6A, and the cathode terminal of the organic light emitting diode OLED may correspond to an upper electrode 340 of FIG. 6A.

The first transistor TR1 may generate the driving current ID. In exemplary embodiments, the first transistor TR1 may operate in a saturation region. In this case, the first transistor TR1 may generate the driving current ID based on a voltage difference between the gate terminal and the source terminal. A gradation may be expressed based on a magnitude of the driving current ID supplied to the organic light emitting diode OLED. As another example, the first transistor TR1 may operate in a linear region. In this case, the gradation may be expressed based on the sum of times during which the driving current is supplied to the organic light emitting diode OLED within one frame.

The gate terminal of the second transistor TR2 may be supplied with the gate signal GW. The first terminal of the second transistor TR2 may be supplied with the data signal DATA. The second terminal of the second transistor TR2 may be connected to the first terminal of the first transistor TR1. For example, the gate signal GW may be provided from a gate driver, and the gate signal GW may be applied to the gate terminal of the second transistor TR2 through the wire for the gate signal GW. The second transistor TR2 may supply the data signal DATA to the first terminal of the first transistor TR1 during an activation period of the gate signal GW. In this case, the second transistor TR2 may operate in a linear region.

The gate terminal of the third transistor TR3 may be supplied with the gate signal GW. The first terminal of the third transistor TR3 may be connected to the gate terminal of the first transistor TR1. The second terminal of the third transistor TR3 may be connected to the second terminal of the first transistor TR1. For example, the gate signal GW may be provided from the gate driver, and the gate signal GW may be applied to the gate terminal of the third transistor TR3 through the wire for the gate signal GW. The third transistor TR3 may connect the gate terminal of the first transistor TR1 to the second terminal of the first transistor TR1 during the activation period of the gate signal GW. In this case, the third transistor TR3 may operate in a linear region. In other words, the third transistor TR3 may diode-connect the first transistor TR1 during the activation period of the gate signal GW. Since the first transistor TR1 is diode-connected, a voltage difference between the first terminal of the first transistor TR1 and the gate terminal of the first transistor TR1 may be as much as a threshold voltage of the first transistor TR1. As a result, a voltage obtained by adding the voltage difference (i.e., threshold voltage) to a voltage of the data signal DATA supplied to the first terminal of the first transistor TR1 may be supplied to the gate terminal of the first transistor TR1 during the activation period of the gate signal GW. In other words, the data signal DATA may be compensated as much as the threshold voltage of the first transistor TR1, and the compensated data signal DATA may be supplied to the gate terminal of the first transistor TR1. As the threshold voltage compensation is performed, a problem of a non-uniform driving current caused by a threshold voltage deviation of the first transistor TR1 may be solved.

An input terminal of the initialization voltage wire provided with the initialization voltage VINT may be connected to a first terminal of the fourth transistor TR4 and a first terminal of the seventh transistor TR7, and an output terminal of the initialization voltage wire may be connected to a second terminal of the fourth transistor TR4 and a first terminal of the storage capacitor CST.

The gate terminal of the fourth transistor TR4 may be supplied with the gate initialization signal GI. The first terminal of the fourth transistor TR4 may be supplied with the initialization voltage VINT. The second terminal of the fourth transistor TR4 may be connected to the gate terminal of the first transistor TR1.

The fourth transistor TR4 may supply the initialization voltage VINT to the gate terminal of the first transistor TR1 during an activation period of the gate initialization signal GI. In this case, the fourth transistor TR4 may operate in a linear region. In other words, the fourth transistor TR4 may initialize the gate terminal of the first transistor TR1 to the initialization voltage VINT during the activation period of the gate initialization signal GI. In exemplary embodiments, the initialization voltage VINT may have a voltage level sufficiently lower than a voltage level of the data signal DATA maintained by the storage capacitor CST in a previous frame, and the initialization voltage VINT may be supplied to the gate terminal of the first transistor TR1. In exemplary embodiments, the initialization voltage may have a voltage level sufficiently higher than the voltage level of the data signal maintained by the storage capacitor in the previous frame, and the initialization voltage may be supplied to the gate terminal of the first transistor.

In exemplary embodiments, the gate initialization signal GI may be a signal which is substantially identical to the gate signal GW transmitted before one horizontal time. For example, the gate initialization signal GI supplied to a sub-pixel circuit in an n^{th} row (where n is an integer of 2 or more) among the sub-pixel circuits included in the OLED display device 100 may be a signal which is substantially identical to the gate signal GW supplied to a sub-pixel circuit in an (n−1)^{th} row among the sub-pixel circuits. In other words, an activated gate initialization signal GI may be supplied to a first sub-pixel circuit in the n^{th} row among the sub-pixel circuits SPC by supplying an activated gate signal GW to a first sub-pixel circuit in the (n−1)^{th} row among the sub-pixel circuits SPC. As a result, the data signal DATA may be supplied to the sub-pixel circuit in the (n−1)^{th} row among the sub-pixel circuits SPC while the gate terminal of the first transistor TR1 included in the sub-pixel circuit in the n^{th} row among the sub-pixel circuits SPC are initialized to the initialization voltage VINT.

The gate terminal of the fifth transistor TR5 may be supplied with the light emission control signal EM. The first terminal of the fifth transistor TR5 may be connected to the wire for the high power supply voltage ELVDD. The second terminal of the fifth transistor TR5 may be connected to the first terminal of the first transistor TR1. For example, the light emission control signal EM may be provided from a light emission control driver, and the light emission control signal EM may be applied to the gate terminal of the fifth transistor TR5 through the wire for the light emission control signal EM. The fifth transistor TR5 may supply the high power supply voltage ELVDD to the first terminal of the first transistor TR1 during an activation period of the light emission control signal EM. On the contrary, the fifth transistor TR5 may shut off the supply of the high power supply voltage ELVDD during a deactivation period of the light emission control signal EM. In this case, the fifth transistor TR5 may operate in a linear region. The fifth transistor TR5 supplies the high power supply voltage ELVDD to the first terminal of the first transistor TR1 during the activation period of the light emission control signal EM, so that the first transistor TR1 may generate the driving current ID. The fifth transistor TR5 shuts off the supply of the high power supply voltage ELVDD during the deactivation period of the light emission control signal EM, so that the data signal DATA supplied to the first terminal of the first transistor TR1 may be supplied to the gate terminal of the first transistor TR1.

The gate terminal of the sixth transistor TR6 (e.g., semiconductor element of FIG. 6A) may be supplied with the light emission control signal EM. The first terminal of the sixth transistor TR6 may be connected to the second terminal of the first transistor TR1. The second terminal of the sixth transistor TR6 may be connected to the first terminal of the organic light emitting diode OLED. The sixth transistor TR6 may supply the driving current ID generated by the first transistor TR1 to the organic light emitting diode OLED during the activation period of the light emission control signal EM. In this case, the sixth transistor TR6 may operate in a linear region. In other words, the sixth transistor TR6 supplies the driving current ID generated by the first transistor TR1 to the organic light emitting diode OLED during the activation period of the light emission control signal EM, so that the organic light emitting diode OLED may output light. The sixth transistor TR6 electrically separates the first transistor TR1 from the organic light emitting diode OLED during the deactivation period of the light emission control signal EM, so that the data signal DATA supplied to the second terminal of the first transistor TR1 (more precisely, data signal which has been subject to threshold voltage compensation) may be supplied to the gate terminal of the first transistor TR1.

The gate terminal of the seventh transistor TR7 may be supplied with the diode initialization signal GB. The first terminal of the seventh transistor TR7 may be supplied with the initialization voltage VINT. The second terminal of the seventh transistor TR7 may be connected to the first terminal of the organic light emitting diode OLED. The seventh transistor TR7 may supply the initialization voltage VINT to the first terminal of the organic light emitting diode OLED during an activation period of the diode initialization signal GB. In this case, the seventh transistor TR7 may operate in the linear region. In other words, the seventh transistor TR7 may initialize the first terminal of the organic light emitting diode OLED to the initialization voltage VINT during the activation period of the diode initialization signal GB.

As another example, the gate initialization signal GI and the diode initialization signal GB may be signals which are substantially identical to each other. An operation of initializing the gate terminal of the first transistor TR1 and an operation of initializing the first terminal of the organic light emitting diode OLED might not affect each other. In other words, the operation of initializing the gate terminal of the first transistor TR1 and the operation of initializing the first terminal of the organic light emitting diode OLED may be independent of each other. Accordingly, the diode initialization signal GB is not separately generated, so that economic efficiency may be optimized.

The storage capacitor CST may include a first terminal and a second terminal. The storage capacitor CST may be connected between the wire for the high power supply voltage ELVDD and the gate terminal of the first transistor TR1. For example, the first terminal of the storage capacitor CST may be connected to the gate terminal of the first transistor TR1, and the second terminal of the storage capacitor CST may be connected to the wire for the high power supply voltage ELVDD. The storage capacitor CST may maintain a voltage level of the gate terminal of the first transistor TR1 during a deactivation period of the gate signal GW. The deactivation period of the gate signal GW may include the activation period of the light emission control signal EM, and the driving current ID generated by the first transistor TR1 may be supplied to the organic light emitting diode OLED during the activation period of the light emission control signal EM. Therefore, the driving current ID generated by the first transistor TR1 may be supplied to the organic light emitting diode OLED based on the voltage level maintained by the storage capacitor CST.

Although the sub-pixel circuit SPC of the invention has been described as including the seven transistors and the one storage capacitor, the configuration of the invention is not limited thereto. For example, the sub-pixel circuit SPC may have a configuration including at least one transistor and at least one storage capacitor.

FIG. 6A is a sectional view taken along line I-I′ of FIG. 3A, and FIG. 6B is a plan view illustrating a light emitting layer and an upper electrode that are disposed on the connection pattern of FIG. 3A. FIG. 6C is a partially enlarged plan view illustrating a region A of FIG. 6B.

Referring to FIGS. 6A, 6B and 6C, the OLED display device 100 may include a substrate 110, a buffer layer 115, a semiconductor element 250, a protective insulating layer 400, a first power supply wire 350, a first planarization layer 270, a wire pattern 215, a connection electrode 235, a second planarization layer 275, a pixel defining layer 310, a sub-pixel structure 200, a capping layer 345, a blocking structure 370, a thin film encapsulation structure 450, etc. In this case, the semiconductor element 250 may include an active layer 130, a gate insulating layer 150, a first gate electrode 170, a first insulating interlayer 190, a second gate electrode 175, a second insulating interlayer 195, a source electrode 210, and a drain electrode 230, and the first power supply wire 350 may include a first sub-power supply wire 351 and a second sub-power supply wire 352. The blocking structure 370 may include a first blocking pattern 371 and a second blocking pattern 372, and the sub-pixel structure 200 may include a lower electrode 290, a light emitting layer 330, and an upper electrode 340. Furthermore, the thin film encapsulation structure 450 may include a first thin film encapsulation layer 451, a second thin film encapsulation layer 452, and a third thin film encapsulation layer 453.

The substrate 110 including transparent or opaque materials may be provided. The substrate 110 may be formed by using a flexible transparent resin substrate. In exemplary embodiments, the substrate 110 may have a configuration in which a first organic layer, a first barrier layer, a second organic layer, and a second barrier layer are sequentially laminated. The first barrier layer and the second barrier layer may include an inorganic material such as silicon oxide, and may block moisture and/or humidity penetrating through the first and second organic layers. The first organic layer and the second organic layer may include an organic material such as a polyimide-based resin, and may have flexibility.

Since the substrate 110 is thin and flexible, the substrate 110 may be formed on a rigid glass substrate to support formation of the semiconductor element 250 and the sub-pixel structure 200. For example, after disposing the buffer layer 115 on the second barrier layer, the semiconductor element 250 and the sub-pixel structure 200 may be formed on the buffer layer 115. After the formation of the semiconductor element 250 and the sub-pixel structure 200, the glass substrate may be removed. In other words, due to flexible physical properties of the substrate 110, it may be difficult to directly form the semiconductor element 250 and the sub-pixel structure 200 on the substrate 110. In consideration of the above point, the glass substrate is removed after the semiconductor element 250 and the sub-pixel structure 200 are formed using the rigid glass substrate, so that the first organic layer, the first barrier layer, the second organic layer, and the second barrier layer may be used as the substrate 110.

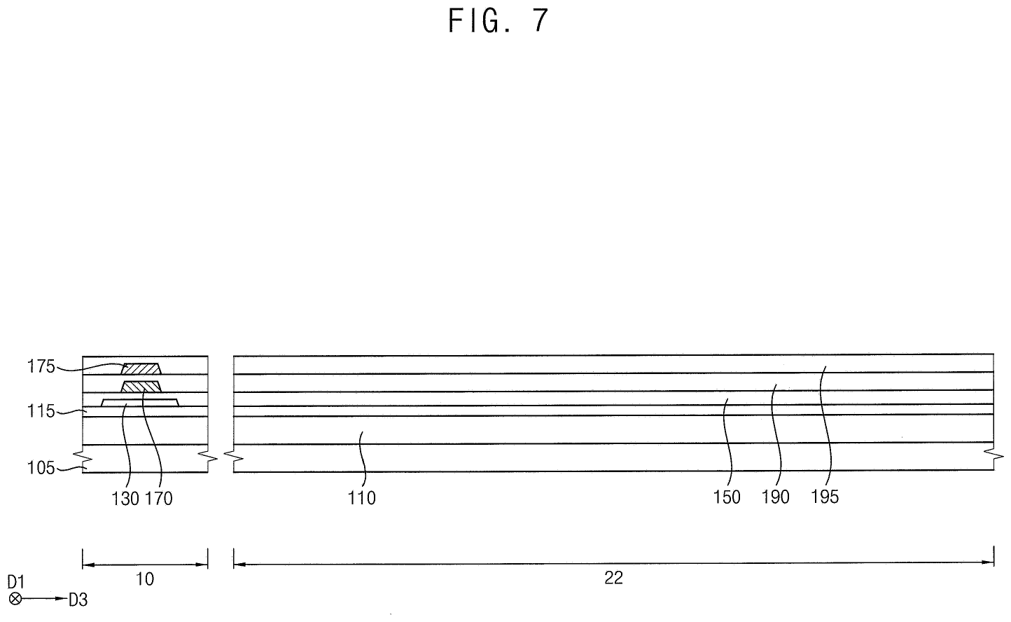

Since the OLED display device 100 includes the display region 10, the peripheral region 20 including the first peripheral region 21, the second peripheral region 22, and the third peripheral region 23, and the pad region 60, as shown in FIGS. 6 and 7, the substrate 110 may also be divided into the display region 10, the first peripheral region 21, and the second peripheral region 22 (see FIG. 1).

As another example, the substrate 110 may include a quartz substrate, a synthetic quartz substrate, a calcium fluoride substrate, a fluorine-doped quartz substrate (F-doped quartz substrate), a soda lime glass substrate, a non-alkali glass substrate, etc.

Although the substrate 110 is described as having four layers, the configuration of the invention is not limited thereto. For example, in exemplary embodiments, the substrate 110 may include a single layer or multiple layers.

The buffer layer 115 may be disposed on the substrate 110. In exemplary embodiments, the buffer layer 115 may be disposed in the display region 10 and the second peripheral region 22 (e.g., peripheral region 20) on the entire substrate 110. The buffer layer 115 may prevent metal atoms or impurities from being diffused from the substrate 110 into the semiconductor element 250, and may control a heat transfer rate during a crystallization process for forming the active layer 130 to obtain a substantially uniform active layer 130. The buffer layer 115 may serve to improve flatness of a surface of the substrate 110 when the surface of the substrate 110 is not uniform. Depending on a type of the substrate 110, at least two buffer layers 115 may be provided on the substrate 110, or the buffer layer 115 might not be provided on the substrate 110. The buffer layer 115 may include a silicon compound, metal oxide, etc. For example, the buffer layer 115 may include silicon oxide (SiOₓ), silicon nitride (SiNₓ), silicon oxynitride (SiOₓN_{y}), silicon oxycarbide (SiOₓC_{y}), silicon carbonitride (SiCₓN_{y}), aluminum oxide (AlOₓ), aluminum nitride (AlNₓ), tantalum oxide (TaOₓ), hafnium oxide (HfOₓ), zirconium oxide (ZrOₓ), titanium oxide (TiOₓ), etc.

The active layer 130 may be disposed in the display region 10 on the buffer layer 115. The active layer 130 may include an oxide semiconductor, an inorganic semiconductor (e.g., amorphous silicon or poly silicon), an organic semiconductor, etc. The active layer 130 may have a source region, a drain region, and a channel region disposed between the source region and the drain region.

The gate insulating layer 150 may be disposed on the active layer 130. The gate insulating layer 150 may cover the active layer 130 in the display region 10 on the buffer layer 115, and may extend in a third direction D3 from the display region 10 to the peripheral region 20 (e.g., the third direction D3 that is perpendicular to the first and second directions D1 and D2). For example, the gate insulating layer 150 may sufficiently cover the active layer 130 on the buffer layer 115, and may have a substantially flat top surface without creating a step around the active layer 130. As another example, the gate insulating layer 150 may cover the active layer 130 on the buffer layer 115 while being disposed along a profile of the active layer 130 with a uniform thickness, or may be disposed in the display region 10 and the second peripheral region 22 on the entire buffer layer 115. The gate insulating layer 150 may include a silicon compound, metal oxide, etc. In exemplary embodiments, the gate insulating layer 150 may have a multilayer structure with multiple insulating layers including materials which are different from each other.

The first gate electrode 170 may be disposed in the display region 10 on the gate insulating layer 150. The first gate electrode 170 may be disposed on a portion of the gate insulating layer 150 under which the active layer 130 is disposed (e.g., to overlap with channel region of active layer 130). The first gate electrode 170 may include a metal, an alloy of a metal, metal nitride, conductive metal oxide, a transparent conductive material, etc. These may be used alone or in combination with each other. In exemplary embodiments, the first gate electrode 170 may have a multilayer structure including multiple layers.

The first insulating interlayer 190 may be disposed on the first gate electrode 170. The first insulating interlayer 190 may cover the first gate electrode 170 in the display region 10 on the gate insulating layer 150, and may extend in the third direction D3 from the display region 10 to the peripheral region 20. For example, the first insulating interlayer 190 may sufficiently cover the first gate electrode 170 on the gate insulating layer 150, and may have a substantially flat top surface without creating a step around the first gate electrode 170. As another example, the first insulating interlayer 190 may cover the first gate electrode 170 on the gate insulating layer 150, and may be disposed along a profile of the first gate electrode 170 with a uniform thickness. The first insulating interlayer 190 may include a silicon compound, metal oxide, etc. In exemplary embodiments, the first insulating interlayer 190 may have a multilayer structure having multiple insulating layers including materials which are different from each other.

The second gate electrode 175 may be disposed in the display region 10 on the first insulating interlayer 190. The second gate electrode 175 may be disposed on a portion of the first insulating interlayer 190 under which the first gate electrode 170 is disposed. As an example, the first gate electrode 170 and the second gate electrode 175 may function as the storage capacitor CST of FIG. 5. The second gate electrode 175 may include a metal, an alloy of a metal, metal nitride, conductive metal oxide, a transparent conductive material, etc. These may be used alone or in combination with each other. In exemplary embodiments, the second gate electrode 175 may have a multilayer structure including multiple layers.

The second insulating interlayer 195 may be disposed on the second gate electrode 175. The second insulating interlayer 195 may cover the second gate electrode 175 in the display region 10 on the first insulating interlayer 190, and may extend in the third direction D3 from the display region 10 to the peripheral region 20. For example, the second insulating interlayer 195 may sufficiently cover the second gate electrode 175 on the first insulating interlayer 190, and may have a substantially flat top surface without creating a step around the second gate electrode 175. As another example, the second insulating interlayer 195 may cover the second gate electrode 175 on the first insulating interlayer 190, and may be disposed along a profile of the second gate electrode 175 with a uniform thickness. The second insulating interlayer 195 may include a silicon compound, metal oxide, etc. In exemplary embodiments, the second insulating interlayer 195 may have a multilayer structure with multiple insulating layers including materials which are different from each other.

The source electrode 210 and the drain electrode 230 may be disposed in the display region 10 on the second insulating interlayer 195. The source electrode 210 may be connected to the source region of the active layer 130 through a contact hole formed by removing first sections of the gate insulating layer 150, the first insulating interlayer 190, and the second insulating interlayer 195, and the drain electrode 230 may be connected to the drain region of the active layer 130 through a contact hole formed by removing second sections of the gate insulating layer 150, the first insulating interlayer 190, and the second insulating interlayer 195. Each of the source electrode 210 and the drain electrode 230 may include a metal, an alloy of a metal, metal nitride, conductive metal oxide, a transparent conductive material, etc. These may be used alone or in combination with each other. In exemplary embodiments, each of the source electrode 210 and the drain electrode 230 may have a multilayer structure including multiple layers.

Accordingly, the semiconductor element 250 including the active layer 130, the gate insulating layer 150, the first gate electrode 170, the first insulating interlayer 190, the second gate electrode 175, the second insulating interlayer 195, the source electrode 210, and the drain electrode 230 may be disposed.

Although the semiconductor element 250 has been described as having a top gate structure, the configuration of the invention is not limited thereto. For example, the semiconductor element 250 may have a bottom gate structure.

Although the OLED display device 100 has been described as including one semiconductor element, the configuration of the invention is not limited thereto. For example, the OLED display device 100 may include at least one semiconductor element and at least one storage capacitor.

The first sub-power supply wire 351 may be disposed in a part of the first peripheral region 21, the second peripheral region 22, and the third peripheral region 23 on the second insulating interlayer 195 (see FIGS. 2 and 6A). The first sub-power supply wire 351 may have a shape of a ring having a lower opening. In exemplary embodiments, the first sub-power supply wire 351 may have the first width W1 in the part of the first peripheral region 21 and the second peripheral region 22, and may have the second width W2 that is less than the first width W1 in the third peripheral region 23. In other words, the first sub-power supply wire 351 may have different widths in the first and second peripheral regions 21 and 22 and the third peripheral region 23.

The first sub-power supply wire 351 may be electrically connected to the pad electrodes 470 of FIG. 2 in the first peripheral region 21. For example, the first sub-power supply wire 351 may be electrically connected to the outermost pad electrodes 470 among the pad electrodes 470. The low power supply voltage ELVSS of FIG. 5 may be applied to the first sub-power supply wire 351, and the low power supply voltage ELVSS may be provided to the upper electrode 340 through the connection pattern 295. The first sub-power supply wire 351 may include a metal, an alloy of a metal, metal nitride, conductive metal oxide, a transparent conductive material, etc. For example, the first sub-power supply wire 351 may include gold (Au), silver (Ag), aluminum (Al), platinum (Pt), nickel (Ni), titanium (Ti), palladium (Pd), magnesium (Mg), calcium (Ca), lithium (Li), chromium (Cr), tantalum (Ta), tungsten (W), copper (Cu), molybdenum (Mo), scandium (Sc), neodymium (Nd), iridium (Ir), an aluminum-containing alloy, aluminum nitride (AlNx), a silver-containing alloy, tungsten nitride (WNx), a copper-containing alloy, a molybdenum-containing alloy, titanium nitride (TiNₓ), chromium nitride (CrNₓ), tantalum nitride (TaNₓ), strontium ruthenium oxide (SrRuₓO_{y}), zinc oxide (ZnOₓ), indium tin oxide (ITO), tin oxide (SnOₓ), indium oxide (InOₓ), gallium oxide (GaOₓ), indium zinc oxide (IZO), etc. These may be used alone or in combination with each other. As another example, the first sub-power supply wire 351 may have a multilayer structure including multiple layers. In exemplary embodiments, the source electrode 210, the drain electrode 230, and the first sub-power supply wire 351 may be disposed on the same layer with each other.

The protective insulating layer 400 may be disposed on the second insulating interlayer 195, the source and drain electrodes 210 and 230, and the first sub-power supply wire 351. The protective insulating layer 400 may cover the source and drain electrodes 210 and 230 in the display region 10 on the second insulating interlayer 195, and may cover the first sub-power supply wire 351 in the second peripheral region 22 on the second insulating interlayer 195. In exemplary embodiments, the protective insulating layer 400 may have a first opening 401 and a second opening 402 for exposing a part of the first sub-power supply wire 351 in the second peripheral region 22. The second sub-power supply wire 352 may be connected to the first sub-power supply wire 351 through the first opening 401 and the second opening 402. The protective insulating layer 400 may have an opening for exposing a part of the drain electrode 230 in the display region 10. The connection electrode 235 may be connected to the drain electrode 230 through the opening disposed in the display region 10. For example, the protective insulating layer 400 may sufficiently cover the source and drain electrodes 210 and 230 and the first sub-power supply wire 351 on the second insulating interlayer 195, and may have a substantially flat top surface without creating a step around the source and drain electrodes 210 and 230, and the first sub-power supply wire 351. As another example, the protective insulating layer 400 may cover the source and drain electrodes 210 and 230 and the first sub-power supply wire 351 on the second insulating interlayer 195, and may be disposed as a substantially uniform thickness along profiles of the source and drain electrodes 210 and 230 and the first sub-power supply wire 351. The protective insulating layer 400 may include a silicon compound, metal oxide, etc. In exemplary embodiments, the protective insulating layer 400 may have a multilayer structure with multiple insulating layers including materials which are different from each other.

The first planarization layer 270 may be disposed on the protective insulating layer 400. The first planarization layer 270 may be disposed in the display region 10 and a part of the second peripheral region 22 on the protective insulating layer 400. In other words, the first planarization layer 270 may cover the protective insulating layer 400 in the display region 10 while extending in the third direction D3, and may expose the first opening 401 and the second opening 402 of the protective insulating layer 400 in the second peripheral region 22. In other words, the first planarization layer 270 may extend from the display region 10 to the second peripheral region 22 to cover at least a part of the first opening 401. For example, the first planarization layer 270 may have a relatively thick thickness, and in this case, the first planarization layer 270 may have a substantially flat top surface. In order to implement such a flat top surface of the first planarization layer 270, a planarization process may be additionally performed on the first planarization layer 270. As another example, the first planarization layer 270 may be disposed along a profile of the protective insulating layer 400 on the protective insulating layer 400 with a uniform thickness. The first planarization layer 270 may be formed of an organic material or an inorganic material. In exemplary embodiments, the first planarization layer 270 may include the organic material. For example, the first planarization layer 270 may include photoresist, a polyacryl-based resin, a polyimide-based resin, a polyamide-based resin, a siloxane-based resin, an acryl-based resin, an epoxy-based resin, etc.

The wire pattern 215 and the connection electrode 235 may be disposed in the display region 10 on the first planarization layer 270. The wire pattern 215 may transmit a gate signal, a data signal, a light emission signal, an initialization signal, a power supply voltage, etc. The connection electrode 235 may be spaced apart from the wire pattern 215 in the display region 10 on the first planarization layer 270. The connection electrode 235 may be connected to the drain electrode 230 through a contact hole formed by removing a part of the first planarization layer 270 disposed in the display region 10, and the connection electrode 235 may electrically connect the lower electrode 290 to the drain electrode 230. As another example, the connection electrode 235 might not be connected to the drain electrode 230, and may electrically connect the semiconductor element 250 to another semiconductor element through the contact hole in another sectional view of the OLED display device 100. Each of the wire pattern 215 and the connection electrode 235 may include a metal, an alloy of a metal, metal nitride, conductive metal oxide, a transparent conductive material, etc. These may be used alone or in combination with each other. In exemplary embodiments, each of the wire pattern 215 and the connection electrode 235 may have a multilayer structure including multiple layers.

The second sub-power supply wire 352 may be disposed in the peripheral region 20 on the first planarization layer 270. The second sub-power supply wire 352 may have a shape of a ring having a lower opening. In exemplary embodiments, the second sub-power supply wire 352 may have the first width W1 in the first peripheral region 21 and the second peripheral region 22, and may have the second width W2 that is less than the first width W1 in the third peripheral region 23. In other words, the second sub-power supply wire 352 may have different widths in the first and second peripheral regions 21 and 22 and the third peripheral region 23.

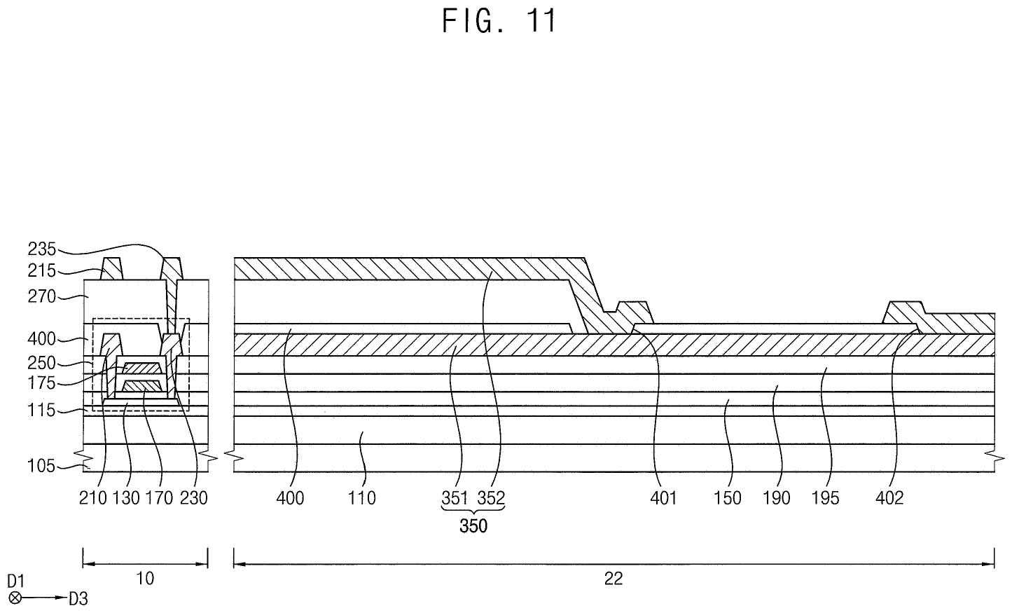

The second sub-power supply wire 352 may make direct contact with the first sub-power supply wire 351 through the first opening 401 in the second peripheral region 22, and may make direct contact with the first sub-power supply wire 351 through the second opening 402. The second sub-power supply wire 352 may have an opening for exposing a top surface of the protective insulating layer 400 between the first opening 401 and the second opening 402 in the second peripheral region 22 (see FIG. 11). As another example, the second sub-power supply wire 352 may be continuously disposed without the opening in the second peripheral region 22.

The second sub-power supply wire 352 may be electrically connected to the pad electrodes 470 of FIG. 2 in the first peripheral region 21. For example, the second sub-power supply wire 352 may be electrically connected to the outermost pad electrodes 470. The low power supply voltage ELVSS may be applied to the second sub-power supply wire 352 through the first sub-power supply wire 351, and the low power supply voltage ELVSS may be provided to the upper electrode 340 through the connection pattern 295. The second sub-power supply wire 352 may include a metal, an alloy of a metal, metal nitride, conductive metal oxide, a transparent conductive material, etc. These may be used alone or in combination with each other. As another example, the second sub-power supply wire 352 may have a multilayer structure including multiple layers. In exemplary embodiments, the wire pattern 215, the connection electrode 235, and the second sub-power supply wire 352 may be disposed on the same layer with each other.

Accordingly, the first power supply wire 350 including the first sub-power supply wire 351 and the second sub-power supply wire 352 may be disposed relative to each other, as described.

Although the first power supply wire 350 has been described as including the first sub-power supply wire 351 and the second sub-power supply wire 352, the configuration of the invention is not limited thereto. For example, the first power supply wire 350 may have a configuration including only the first sub-power supply wire 351, a configuration including only the second sub-power supply wire 352, or a configuration including the first sub-power supply wire 351, the second sub-power supply wire 352, and an additional wire.

Although the first sub-power supply wire 351 and the second sub-power supply wire 352 have been described as having the first width W1 in the second peripheral region 22 and as having the second width W2 in the third peripheral region 23, the configuration of the invention is not limited thereto. For example, in exemplary embodiments, only one of the first sub-power supply wire 351 and the second sub-power supply wire 352 may have the first width W1 in the second peripheral region 22.

The second planarization layer 275 may be disposed on the wire pattern 215, the connection electrode 235, the second sub-power supply wire 352, and the first planarization layer 270. The second planarization layer 275 may cover the wire pattern 215 and the connection electrode 235 in the display region 10 on the first planarization layer 270 while extending in the third direction D3 so as to cover the second sub-power supply wire 352 in the second peripheral region 22. In exemplary embodiments, as shown in FIG. 6C, the second planarization layer 275 may have openings 490 for exposing a top surface of the second sub-power supply wire 352 in the second peripheral region 22. The connection pattern 295 may make direct contact with the second sub-power supply wire 352 through the openings 490 of the second planarization layer 275. The openings 490 may be formed in a portion where the first power supply wire 350 and the connection pattern 295 are overlapped with each other in the third peripheral region 23. In other words, the openings 490 may be formed in the second planarization layer 275 so as not to be overlapped with the light emitting layer 330 in the second peripheral region 22 and the third peripheral region 23 on the first planarization layer 270. Moreover, the second planarization layer 275 may cover an end of the second sub-power supply wire 352 disposed in the first opening 401 in the second peripheral region 22.

When referring to the conventional OLED display device shown in FIG. 3B, the first and second power supply wires 1350 and 1390 may be disposed together in the peripheral region 20. In other words, a second portion of the second power supply wire 1390 may be disposed in a part of the first peripheral region 21 as well as the second peripheral region 22. Therefore, the first power supply wire 1350 may have a relatively reduced width in the first peripheral region 21 and the second peripheral region 22. In other words, the first power supply wire 1350 may have a substantially identical width throughout the peripheral region 20. In this case, a portion where the first power supply wire 1350 and the connection pattern 1295 are overlapped with each other may be relatively reduced in the second peripheral region 22. As a result, the number of the openings formed in the second planarization layer 275 in the second peripheral region 22 may be relatively small. When the conventional organic light emitting diode display device is driven at a high luminance, a current may be concentrated on the first power supply wire 1350 disposed in the first peripheral region 21 and the second peripheral region 22, thereby causing an amount of heat that is generated to be excessive. When there is excessive heat generation, the first power supply wire 1350 may be short-circuited, or an insulating layer disposed around the first power supply wire 1350 may be deformed due to the excessive heat generation, and may thus render the conventional OLED display device as defective. Yet, in exemplary embodiments of the invention, the first power supply wire 350 and the connection pattern 295 have a relatively wide width the first peripheral region 21 and the second peripheral region 22, so that a relatively greater number of openings 490 for allowing the connection pattern 295 to make direct contact with the first power supply wire 350 in the second peripheral region 22 may be formed. Accordingly, in the OLED display device 100, heat that is generated in the first power supply wire 350 the first peripheral region 21 and the second peripheral region 22 may be relatively reduced, when compared to the conventional OLED display device. As will be understood, this is due, in part, to the increase in the number of openings 490 in the second planarization layer 275 enabling connection of the first power supply line 350 with the connection pattern 295 over a correspondingly increased areas of the first power supply wire 350 and the connection pattern 295.

Referring again to FIGS. 6A, 6B, and 6C, the second planarization layer 275 may have a relatively thick thickness to sufficiently cover the wire pattern 215, the connection electrode 235, and the second sub-power supply wire 352, and in this case, the second planarization layer 275 may have a substantially flat top surface. In order to implement such a flat top surface of the second planarization layer 275, the planarization process may be additionally performed on the second planarization layer 275. As an example, the second planarization layer 275 may cover the wire pattern 215, the connection electrode 235, and the second sub-power supply wire 352, and may be disposed along profiles of the wire pattern 215, the connection electrode 235, and the second sub-power supply wire 352 with a uniform thickness. The second planarization layer 275 may be formed of an organic material or an inorganic material. In exemplary embodiments, the second planarization layer 275 may include the organic material.

The first blocking pattern 371 may be disposed in the peripheral region 20 on the protective insulating layer 400 and the first sub-power supply wire 351. The first blocking pattern 371 may be spaced apart from the second planarization layer 275 in the third direction D3, and may cover a first end of the second sub-power supply wire 352 disposed in the second opening 402. For example, the first blocking pattern 371 may be disposed along a profile of an outer peripheral edge of the display region 10. In other words, the first blocking pattern 371 may surround the display region 10 in the first peripheral region 21, the second peripheral region 22, and the third peripheral region 23. In exemplary embodiments, the first blocking pattern 371 may serve to block leakage of the second thin film encapsulation layer 452. The first blocking pattern 371 may include an organic material or an inorganic material. In exemplary embodiments, the first blocking pattern 371 may include the organic material. Top surfaces of the second planarization layer 275 and the first blocking pattern 371 may be at the same level.

The lower electrode 290 may be disposed in the display region 10 on the second planarization layer 275. The lower electrode 290 may be connected to the connection electrode 235 through a contact hole formed by removing a part of the second planarization layer 275, and the lower electrode 290 may be electrically connected to the semiconductor element 250. The lower electrode 290 may include a metal, an alloy of a metal, metal nitride, conductive metal oxide, a transparent conductive material, etc. These may be used alone or in combination with each other. In exemplary embodiments, the lower electrode 290 may have a multilayer structure including multiple layers.

The connection pattern 295 may be disposed in the peripheral region 20 on the second planarization layer 275, the protective insulating layer 400, the first blocking pattern 371, and the second sub-power supply wire 352. The connection pattern 295 may have a shape of a lower opening ring. The connection pattern 295 may be disposed on the second planarization layer 275, inner sides of the openings 490 of the second planarization layer 275, the protective insulating layer 400 disposed between the second planarization layer 275 and the first blocking pattern 371, the first blocking pattern 371, and the second sub-power supply wire 352 disposed in the second opening 402, and may extend in the third direction D3. In other words, the connection pattern 295 may be disposed along profiles of the second planarization layer 275, the protective insulating layer 400, the first blocking pattern 371, and the second sub-power supply wire 352. The connection pattern 295 may include a metal, an alloy of a metal, metal nitride, conductive metal oxide, a transparent conductive material, etc. These may be used alone or in combination with each other. In exemplary embodiments, the connection pattern 295 may have a multilayer structure including multiple layers, and a top surface of the lower electrode 290 and an uppermost surface of the connection pattern 295 may be at the same level.

The pixel defining layer 310 may be disposed in the display region 10 and the second peripheral region 22 on the second planarization layer 275. The pixel defining layer 310 may expose a part of the lower electrode 290 in the display region 10 while extending in the third direction D3, and may be disposed on the connection pattern 295 while exposing the connection pattern 295 disposed in the openings 490 in the second peripheral region 22. The pixel defining layer 310 may be formed of an organic material or an inorganic material. In exemplary embodiments, the pixel defining layer 310 may include the organic material.

The second blocking pattern 372 may be disposed in the peripheral region 20 on the connection pattern 295. The second blocking pattern 372 may be spaced apart from the pixel defining layer 310 in the third direction D3, and may cover the connection pattern 295 disposed on the first blocking pattern 371. For example, the second blocking pattern 372 may extend in the first direction D1, and may be disposed along a profile of the display region 10. In other words, the second blocking pattern 372 may surround the display region 10 in the first peripheral region 21, the second peripheral region 22, and the third peripheral region 23. In exemplary embodiments, the second blocking pattern 372 may serve to block leakage of the second thin film encapsulation layer 452 together with the first blocking pattern 371. The second blocking pattern 372 may include an organic material or an inorganic material. In exemplary embodiments, the second blocking pattern 372 may include the organic material. Top surfaces of the pixel defining layer 310 and the second blocking pattern 372 may be at the same level.

Accordingly, the blocking structure 370 including the first blocking pattern 371 and the second blocking pattern 372 may be disposed.

Although the OLED display device 100 has been described as including one blocking structure 370, the configuration of the invention is not limited thereto. For example, in exemplary embodiments, at least one blocking structure may be further provided while being spaced apart from the blocking structure 370 in the direction from the display region 10 to the peripheral region 20. In other words, the OLED display device 100 may include at least two blocking structures.

A portion formed between the pixel defining layer 310 and the blocking structure 370 may be defined as a first blocking region. The first blocking region may be disposed parallel to the blocking structure 370, and the first planarization layer 270, the second planarization layer 275, and the pixel defining layer 310 might not be disposed in the first blocking region. For example, in order to prevent moisture of humidity from penetrating into the display region 10 through the first planarization layer 270, the second planarization layer 275, and the pixel defining layer 310 disposed in the peripheral region 20, the first planarization layer 270, the second planarization layer 275, and the pixel defining layer 310 might not be disposed in the first blocking region. In exemplary embodiments, when the OLED display device 100 further includes an additional blocking structure, a second blocking region may be additionally formed between the blocking structure 370 and the additional blocking structure.

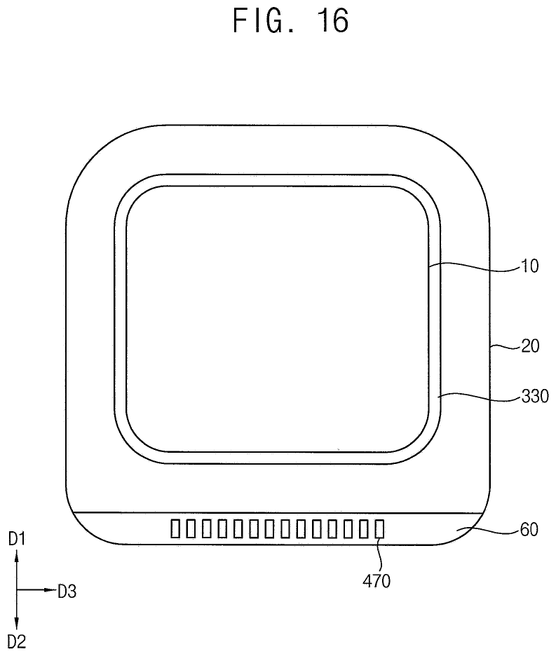

The light emitting layer 330 may be disposed in the display region 10 and a part of the peripheral region 20 on the substrate 110 (see FIGS. 6B, 6C, and 16). For example, the light emitting layer 330 may be disposed on the pixel defining layer 310 and the lower electrode 290 in the display region 10 while extending in the third direction D3, and may be disposed on a part of the pixel defining layer 310 in the peripheral region 20. In other words, the light emitting layer 330 may be disposed along profiles of the pixel defining layer 310 and the lower electrode 290. In exemplary embodiments, the light emitting layer 330 might not be overlapped with the openings 490.

The light emitting layer 330 may have a multilayer structure including an organic light emission layer (“EML”), a hole injection layer (“HIL”), a hole transport layer (“HTL”), an electron transport layer (“ETL”), an electron injection layer (“EIL”), etc. In exemplary embodiments, the EML, the HIL, the HTL, the ETL, and the EIL may be disposed in the peripheral region 20. In exemplary embodiments, the HIL, the HTL, the ETL, and the EIL may be disposed in the peripheral region 20 except for the EML.

The EML of the light emitting layer 330 may be formed using at least one of light emitting materials for emitting different color lights (i.e., red light, green light, blue light, etc.) according to sub-pixels. As an example, the EML of the light emitting layer 330 may be formed by laminating light emitting materials for emitting the different color lights such as red light, green light, or blue light to emit white light as a whole. In this case, a color filter may be disposed on the light emitting layer 330 which is disposed on the lower electrode 290. The color filter may include at least one of a red color filter, a green color filter, and a blue color filter. As another example, the color filter may include a yellow color filter, a cyan color filter, and a magenta color filter. The color filter may include a photosensitive resin or color photoresist.

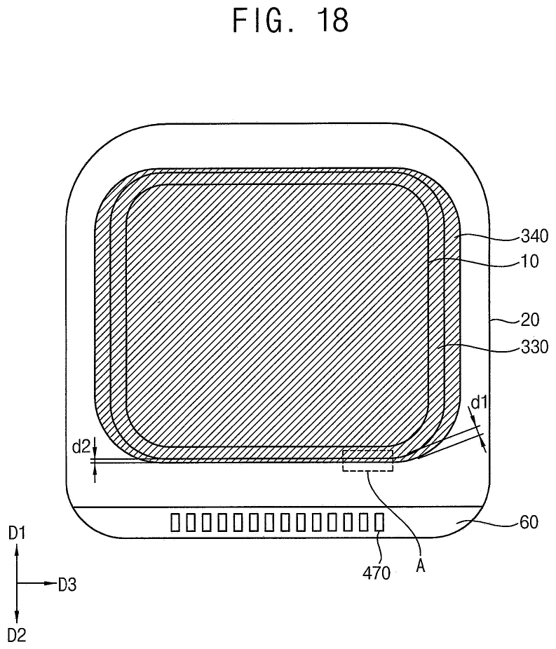

The upper electrode 340 may be disposed in the display region 10 and a part of the peripheral region 20 on the substrate 110 (see FIGS. 6B, 6C, and 18). For example, the upper electrode 340 may be disposed on the light emitting layer 330 in the display region 10 while extending in the third direction D3, and may be disposed over the light emitting layer 330, a part of the pixel defining layer 310, and the connection pattern 295 disposed in the openings 490 in the peripheral region 20. In other words, the upper electrode 340 may be disposed along profiles of the light emitting layer 330, the pixel defining layer 310, and the connection pattern 295. In exemplary embodiments, the upper electrode 340 may make direct contact with the connection pattern 295 disposed in the openings 490, and may receive the low power supply voltage ELVSS from the connection pattern 295. The upper electrode 340 may include a metal, an alloy of a metal, metal nitride, conductive metal oxide, a transparent conductive material, etc. These may be used alone or in combination with each other. In exemplary embodiments, the upper electrode 340 may have a multilayer structure including multiple layers.

Accordingly, the sub-pixel structure 200 including the lower electrode 290, the light emitting layer 330, and the upper electrode 340 may be disposed.

The capping layer 345 may be disposed in the display region 10 and a part of the second peripheral region 22 on the substrate 110. For example, the capping layer 345 may be disposed on the upper electrode 340 in the display region 10 while extending in the third direction D3, and may be disposed on the upper electrode 340 in the peripheral region 20. In other words, the capping layer 345 may be disposed along a profile of the upper electrode 340 in the display region 10 and the peripheral region 20. In exemplary embodiments, the capping layer 345 may be overlapped with the upper electrode 340 in the peripheral region 20. The capping layer 345 may protect the sub-pixel structure 200, and may include an organic material or an inorganic material. In exemplary embodiments, the capping layer 345 may include a triamine derivative, an arylenediamine derivative, 4,4′-N,N′-dicarbazole-biphenyl (4,4′-bis(N-carbazolyl)-1,1′-biphenyl)(CBP), tris-8-hydroxyquinoline aluminum (Alq3), etc.

The first thin film encapsulation layer 451 may be disposed in the display region 10 and the peripheral region 20 on the substrate 110. For example, the first thin film encapsulation layer 451 may be disposed on the capping layer 345 in the display region 10 while extending in the third direction D3, and may be disposed on the capping layer 345, the pixel defining layer 310, the blocking structure 370, and the connection pattern 295 in the peripheral region 20. In other words, the first thin film encapsulation layer 451 may be disposed along profiles of the capping layer 345, the pixel defining layer 310, the blocking structure 370, and the connection pattern 295. In exemplary embodiments, the first thin film encapsulation layer 451 may make direct contact with the capping layer 345 in the openings 490, and may make direct contact with the connection pattern 295 in the blocking region (e.g., portion disposed between pixel defining layer 310 and blocking structure 370 in second peripheral region 22). The first thin film encapsulation layer 451 may prevent the sub-pixel structure 200 from being deteriorated due to penetration of moisture, oxygen, etc. The first thin film encapsulation layer 451 may function to protect the sub-pixel structure 200 from an external impact. The first thin film encapsulation layer 451 may include flexible inorganic materials.

The second thin film encapsulation layer 452 may be disposed in the display region 10 and a part of the peripheral region 20 on the first thin film encapsulation layer 451. The second thin film encapsulation layer 452 may be overlapped with a part of a side wall of the blocking structure 370. As another example, the second thin film encapsulation layer 452 might not be overlapped with the blocking structure 370, or may cover the blocking structure 370 while extending in the third direction D3. The second thin film encapsulation layer 452 may improve flatness of the OLED display device 100, and may protect the sub-pixel structure 200. The second thin film encapsulation layer 452 may include flexible organic materials.

The third thin film encapsulation layer 453 may be disposed on the second thin film encapsulation layer 452 and the first thin film encapsulation layer 451. The third thin film encapsulation layer 453 may cover the second thin film encapsulation layer 452 in the display region 10 while being disposed along a profile of the second thin film encapsulation layer 452 with a uniform thickness, and may extend to the peripheral region 20. The third thin film encapsulation layer 453 may be disposed along profiles of the first thin film encapsulation layer 451 and a part of the second thin film encapsulation layer 452 in the peripheral region 20. The third thin film encapsulation layer 453 may prevent the sub-pixel structure 200 from being deteriorated due to the penetration of moisture, oxygen, etc., together with the first thin film encapsulation layer 451. The third thin film encapsulation layer 453 may function to protect the sub-pixel structure 200 from an external impact together with the first thin film encapsulation layer 451 and the second thin film encapsulation layer 452. The third thin film encapsulation layer 453 may include flexible inorganic materials.

Accordingly, the thin film encapsulation structure 450 including the first thin film encapsulation layer 451, the second thin film encapsulation layer 452, and the third thin film encapsulation layer 453 may be disposed. As an example, the thin film encapsulation structure 450 may have a five-layer structure formed by laminating first to fifth thin film encapsulation layers or a seven-layer structure formed by laminating first to seventh thin film encapsulation layers.

As described above, the OLED display device 100 shown in FIGS. 6 and 7 may be provided.

The OLED display device 100 according to exemplary embodiments of the invention includes the first power supply wire 350 and the connection pattern 295 that are disposed to each have a relatively wide width, that is greater than the width W2, in at least the second peripheral region 22. Because each of the first power supply wire 350 and the connection pattern 295 are so disposed, an amount of heat that is generated by the first power supply wire 350, as a result of direct connection with the connection pattern 295 through its openings 490, may be reduced, as described above.

In view of the above, the OLED device 100 of the invention includes the first power supply wire 350, the second power supply wire 390, and the connection pattern 390 which are operable to power the OLED device 100. The first power supply wire 350 is disposed in each of the first peripheral region 21, the second peripheral region 22, and the third peripheral region 23. A width of the first power supply wire 350 in the second peripheral region 22 is the width W1, which is greater than the width W2 thereof in the third peripheral region 23. Because of this configuration, an amount of heat that is generated by operation of the first power supply wire 350, via connection with the connection pattern 295, may be reduced by, for example, distribution thereof across increased areas of the first supply wire 350 and connection pattern 295. As has been discussed above, the width W1 of the first power supply wire 350, and the width of the connection pattern 295 in the second peripheral region 22 is a result of, at least, the second power supply wire 390 being excluded from, i.e., not disposed or contained in, the second peripheral region 22.

FIGS. 7 to 19 are views illustrating a method of manufacturing an OLED display device according to exemplary embodiments of the invention. For example, FIGS. 7 to 15, 17, and 19 are sectional views illustrating the method of manufacturing the OLED display device, FIG. 16 is a plan view illustrating a light emitting layer included in the OLED display device, and FIG. 18 is a plan view for explaining an upper electrode included in the OLED display device.

Referring to FIG. 7, a rigid glass substrate 105 may be provided. The substrate 110 including transparent or opaque materials may be formed on the rigid glass substrate 105. The substrate 110 may be formed by using a flexible transparent resin substrate. In exemplary embodiments, the substrate 110 may have a configuration in which the first organic layer, the first barrier layer, the second organic layer, and the second barrier layer are sequentially laminated. The first barrier layer and the second barrier layer may include an inorganic material such as silicon oxide. The first organic layer and the second organic layer may include an organic material such as a polyimide-based resin. In this case, each of the first and second barrier layers may block moisture penetrating through the first and second organic layers.

A buffer layer 115 may be formed on the substrate 110. In exemplary embodiments, the buffer layer 115 may be formed in the display region 10 and the second peripheral region 22 on the entire substrate 110. Depending on the type of the substrate 110, at least two buffer layers 115 may be provided on the substrate 110, or the buffer layer 115 might not be provided on the substrate 110. The buffer layer 115 may be formed using a silicon compound, metal oxide, etc. For example, the buffer layer 115 may include SiOₓ, SiNₓ, SiOₓN_{y}, SiOₓC_{y}, SiCₓN_{y}, AlOₓ, AlNₓ, TaOₓ, HfOₓ, ZrOₓ, TiOₓ, etc.

An active layer 130 may be formed in the display region 10 on the buffer layer 115. The active layer 130 may be formed using an oxide semiconductor, an inorganic semiconductor, an organic semiconductor, etc. The active layer 130 may have a source region, a drain region, and a channel region disposed between the source region and the drain region.

A gate insulating layer 150 may be formed on the active layer 130. The gate insulating layer 150 may cover the active layer 130 in the display region 10 on the buffer layer 115, and may extend in the third direction D3 from the display region 10 to the peripheral region 20. For example, the gate insulating layer 150 may sufficiently cover the active layer 130 on the buffer layer 115, and may have a substantially flat top surface without creating a step around the active layer 130. As another example, the gate insulating layer 150 may cover the active layer 130 on the buffer layer 115 while being formed along the profile of the active layer 130 with a uniform thickness, or may be formed in the display region 10 and the second peripheral region 22 on the entire buffer layer 115. The gate insulating layer 150 may be formed using a silicon compound, metal oxide, etc. In exemplary embodiments, the gate insulating layer 150 may have a multilayer structure with multiple insulating layers including materials which are different from each other.

A first gate electrode 170 may be formed in the display region 10 on the gate insulating layer 150. The first gate electrode 170 may be formed on a portion of the gate insulating layer 150 under which the active layer 130 is disposed. The first gate electrode 170 may be formed using a metal, an alloy of a metal, metal nitride, conductive metal oxide, a transparent conductive material, etc. These may be used alone or in combination with each other. In exemplary embodiments, the first gate electrode 170 may have a multilayer structure including multiple layers.

A first insulating interlayer 190 may be formed on the first gate electrode 170. The first insulating interlayer 190 may cover the first gate electrode 170 in the display region 10 on the gate insulating layer 150, and may extend in the third direction D3. For example, the first insulating interlayer 190 may sufficiently cover the first gate electrode 170 on the gate insulating layer 150, and may have a substantially flat top surface without creating a step around the first gate electrode 170. As another example, the first insulating interlayer 190 may cover the first gate electrode 170 on the gate insulating layer 150, and may be formed along the profile of the first gate electrode 170 with a uniform thickness. The first insulating interlayer 190 may be formed using a silicon compound, metal oxide, etc. In exemplary embodiments, the first insulating interlayer 190 may have a multilayer structure having multiple insulating layers including materials which are different from each other.

A second gate electrode 175 may be formed in the display region 10 on the first insulating interlayer 190. The second gate electrode 175 may be formed on a portion of the first insulating interlayer 190 under which the first gate electrode 170 is disposed. The second gate electrode 175 may be formed using a metal, an alloy of metal, metal nitride, conductive metal oxide, a transparent conductive material, etc. These may be used alone or in combination with each other. In exemplary embodiments, the second gate electrode 175 may have a multilayer structure including multiple layers.

A second insulating interlayer 195 may be formed on the second gate electrode 175. The second insulating interlayer 195 may cover the second gate electrode 175 in the display region 10 on the first insulating interlayer 190, and may extend in the third direction D3. For example, the second insulating interlayer 195 may sufficiently cover the second gate electrode 175 on the first insulating interlayer 190, and may have a substantially flat top surface without creating a step around the second gate electrode 175. As another example, the second insulating interlayer 195 may cover the second gate electrode 175 on the first insulating interlayer 190, and may be formed along the profile of the second gate electrode 175 with a uniform thickness. The second insulating interlayer 195 may be formed using a silicon compound, metal oxide, etc. In exemplary embodiments, the second insulating interlayer 195 may have a multilayer structure with multiple insulating layers including materials which are different from each other.

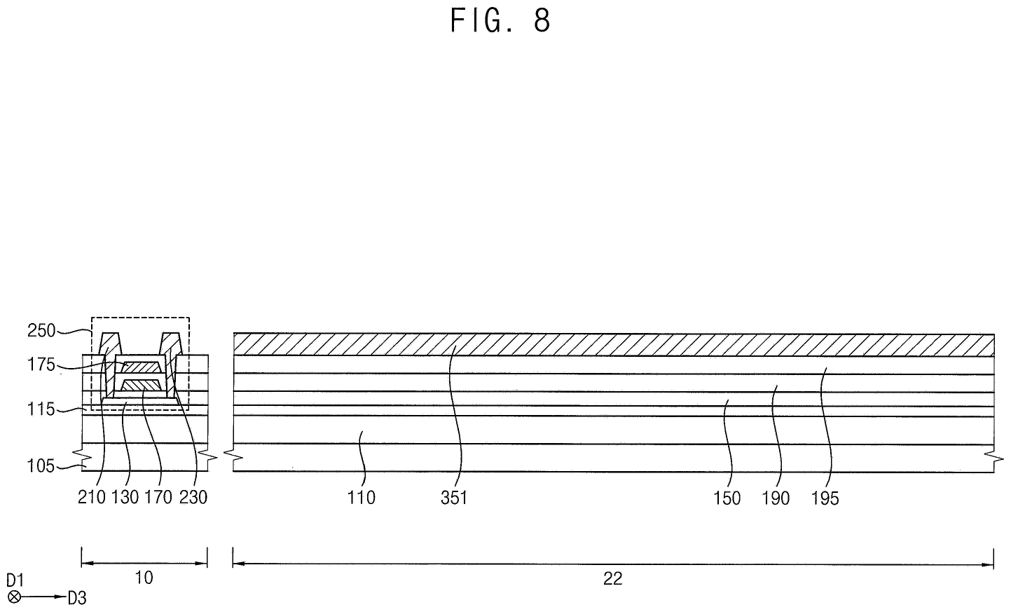

Referring to FIG. 8, a source electrode 210 and a drain electrode 230 may be formed in the display region 10 on the second insulating interlayer 195. The source electrode 210 may be connected to the source region of the active layer 130 through the contact hole formed by removing the first sections of the gate insulating layer 150, the first insulating interlayer 190, and the second insulating interlayer 195, and the drain electrode 230 may be connected to the drain region of the active layer 130 through the contact hole formed by removing the second sections of the gate insulating layer 150, the first insulating interlayer 190, and the second insulating interlayer 195. Each of the source electrode 210 and the drain electrode 230 may be formed using a metal, an alloy of a metal, metal nitride, conductive metal oxide, a transparent conductive material, etc. These may be used alone or in combination with each other. In exemplary embodiments, each of the source electrode 210 and the drain electrode 230 may have a multilayer structure including multiple layers.

Accordingly, a semiconductor element 250 including the active layer 130, the gate insulating layer 150, the first gate electrode 170, the first insulating interlayer 190, the second gate electrode 175, the second insulating interlayer 195, the source electrode 210, and the drain electrode 230 may be formed in view of the above.

A first sub-power supply wire 351 may be formed in a part of the first peripheral region 21, the second peripheral region 22, and the third peripheral region 23 on the second insulating interlayer 195 (see FIG. 2). In exemplary embodiments, the first sub-power supply wire 351 may have the first width W1 in the second peripheral region 22, and may have the second width W2 that is less than the first width W1 in the third peripheral region 23. In other words, the first sub-power supply wire 351 may have different widths in the second peripheral region 22 and the third peripheral region 23. The first sub-power supply wire 351 may be formed using a metal, an alloy of a metal, metal nitride, conductive metal oxide, a transparent conductive material, etc. For example, the first sub-power supply wire 351 may be formed using Au, Ag, Al, Pt, Ni, Ti, Pd, Mg, Ca, Li, Cr, Ta, W, Cu, Mo, Sc, Nd, Ir, an aluminum-containing alloy, AlNₓ, a silver-containing alloy, WNₓ, a copper-containing alloy, a molybdenum-containing alloy, TiNₓ, CrNₓ, TaNₓ, SrRuₓO_{y}, ZnOₓ, ITO, SnOₓ, InOₓ, GaOₓ, IZO, etc. These may be used alone or in combination with each other. As another example, the first sub-power supply wire 351 may have a multilayer structure including multiple layers. In exemplary embodiments, the source electrode 210, the drain electrode 230, and the first sub-power supply wire 351 may be formed simultaneously using an identical material on the same layer with each other.

For example, after a preliminary first electrode layer is formed on the second insulating interlayer 195, the preliminary first electrode layer may be partially etched to simultaneously form the source electrode 210, the drain electrode 230, and the first sub-power supply wire 351.

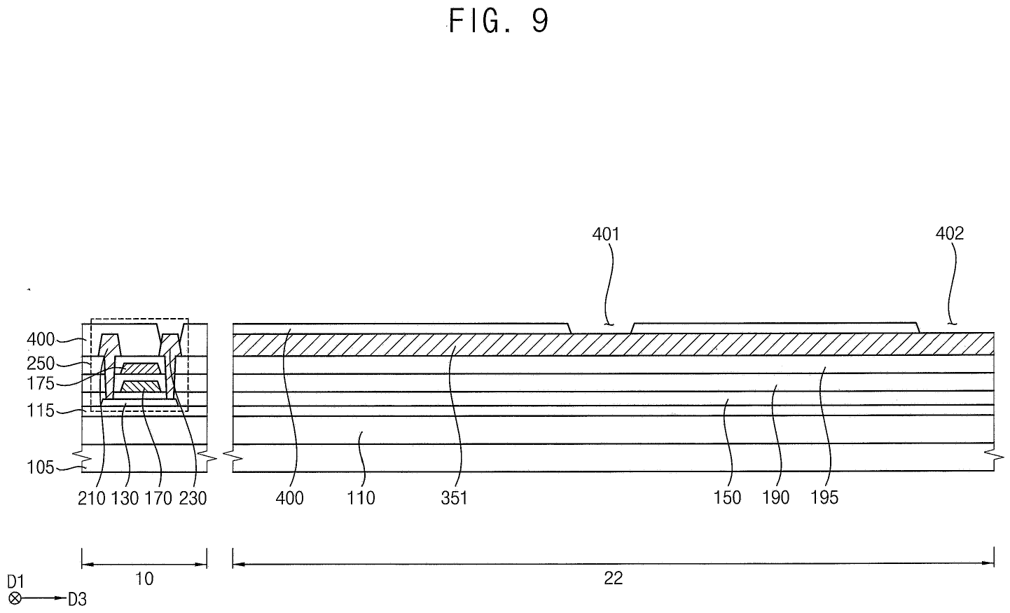

Referring to FIG. 9, a protective insulating layer 400 may be formed on the second insulating interlayer 195, the source and drain electrodes 210 and 230, and the first sub-power supply wire 351. The protective insulating layer 400 may cover the source and drain electrodes 210 and 230 in the display region 10 on the second insulating interlayer 195, and may cover the first sub-power supply wire 351 in the second peripheral region 22 on the second insulating interlayer 195. In exemplary embodiments, the protective insulating layer 400 may have a first opening 401 and a second opening 402 for exposing a part of the first sub-power supply wire 351 in the second peripheral region 22. The protective insulating layer 400 may have an opening for exposing a part of the drain electrode 230 in the display region 10. For example, the protective insulating layer 400 may sufficiently cover the source and drain electrodes 210 and 230 and the first sub-power supply wire 351 on the second insulating interlayer 195, and may have a substantially flat top surface without creating a step around the source and drain electrodes 210 and 230, and the first sub-power supply wire 351. As another example, the protective insulating layer 400 may cover the source and drain electrodes 210 and 230 and the first sub-power supply wire 351 on the second insulating interlayer 195, and may be formed as a substantially uniform thickness along the profiles of the source and drain electrodes 210 and 230 and the first sub-power supply wire 351. The protective insulating layer 400 may be formed using a silicon compound, metal oxide, etc. In exemplary embodiments, the protective insulating layer 400 may have a multilayer structure with multiple insulating layers including materials which are different from each other.

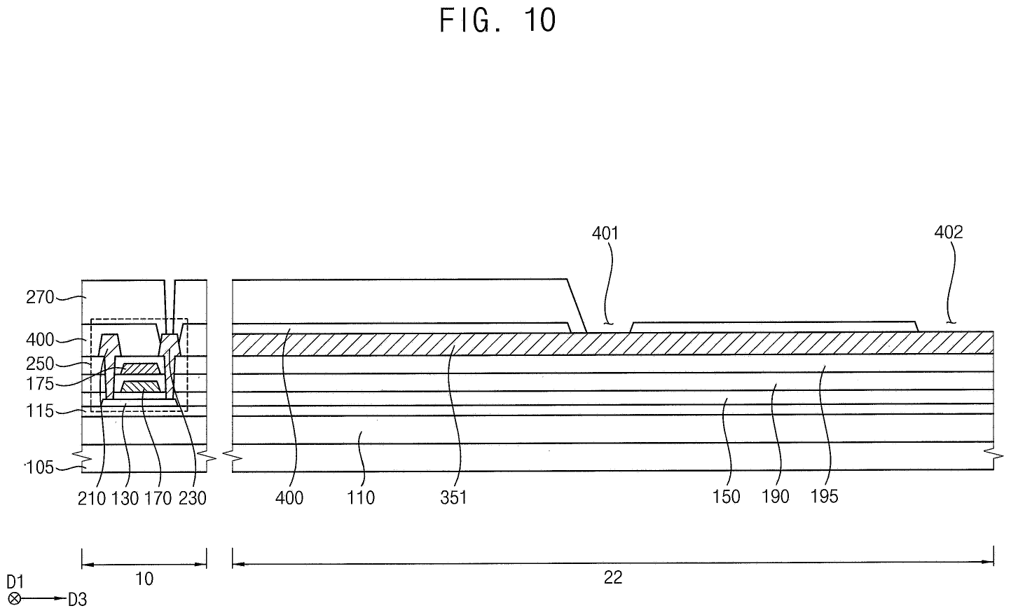

Referring to FIG. 10, a first planarization layer 270 may be formed on the protective insulating layer 400. The first planarization layer 270 may be formed in the display region 10 and a part of the second peripheral region 22 on the protective insulating layer 400. In other words, the first planarization layer 270 may cover the protective insulating layer 400 in the display region 10 while extending in the third direction D3, and may expose the first opening 401 and the second opening 402 of the protective insulating layer 400 in the peripheral region 20. In other words, the first planarization layer 270 may extend from the display region 10 to the peripheral region 20 to cover at least a part of the first opening 401. The first planarization layer 270 may have a contact hole for exposing a part of the drain electrode 230. For example, the first planarization layer 270 may have a relatively thick thickness, and in this case, the first planarization layer 270 may have a substantially flat top surface. In order to implement such a flat top surface of the first planarization layer 270, the planarization process may be additionally performed on the first planarization layer 270. As another example, the first planarization layer 270 may be formed along the profile of the protective insulating layer 400 on the protective insulating layer 400 with a uniform thickness. The first planarization layer 270 may be formed using an organic material. For example, the first planarization layer 270 may include photoresist, a polyacryl-based resin, a polyimide-based resin, a polyamide-based resin, a siloxane-based resin, an acryl-based resin, an epoxy-based resin, etc.

Referring to FIG. 11, a wire pattern 215 and a connection electrode 235 may be formed in the display region 10 on the first planarization layer 270. The connection electrode 235 may be spaced apart from the wire pattern 215 in the display region 10 on the first planarization layer 270. The connection electrode 235 may be connected to the drain electrode 230 through the contact hole of the first planarization layer 270 disposed in the display region 10. Each of the wire pattern 215 and the connection electrode 235 may be formed using a metal, an alloy of a metal, metal nitride, conductive metal oxide, a transparent conductive material, etc. These may be used alone or in combination with each other. In exemplary embodiments, each of the wire pattern 215 and the connection electrode 235 may have a multilayer structure including multiple layers.

A second sub-power supply wire 352 may be formed in the peripheral region 20 on the first planarization layer 270 (see FIG. 2). In exemplary embodiments, the second sub-power supply wire 352 may have the first width W1 in the second peripheral region 22, and may have the second width W2 that is less than the first width W1 in the third peripheral region 23. In other words, the second sub-power supply wire 352 may have different widths in the second peripheral region 22 and the third peripheral region 23. The second sub-power supply wire 352 may make direct contact with the first sub-power supply wire 351 through the first opening 401 in the second peripheral region 22, and may make direct contact with the first sub-power supply wire 351 through the second opening 402. The second sub-power supply wire 352 may have the opening for exposing the top surface of the protective insulating layer 400 between the first opening 401 and the second opening 402 in the second peripheral region 22. As another example, the second sub-power supply wire 352 may be continuously formed without the opening in the second peripheral region 22. The second sub-power supply wire 352 may be formed using a metal, an alloy of a metal, metal nitride, conductive metal oxide, a transparent conductive material, etc. These may be used alone or in combination with each other. As another example, the second sub-power supply wire 352 may have a multilayer structure including multiple layers. In exemplary embodiments, the wire pattern 215, the connection electrode 235, and the second sub-power supply wire 352 may be formed simultaneously using an identical material on the same layer with each other.

For example, after a preliminary second electrode layer is formed on the first planarization layer 270, the first sub-power supply wire 351, and the protective insulating layer 400, the preliminary second electrode layer may be partially etched to simultaneously form the wire pattern 215, the connection electrode 235, and the second sub-power supply wire 352.

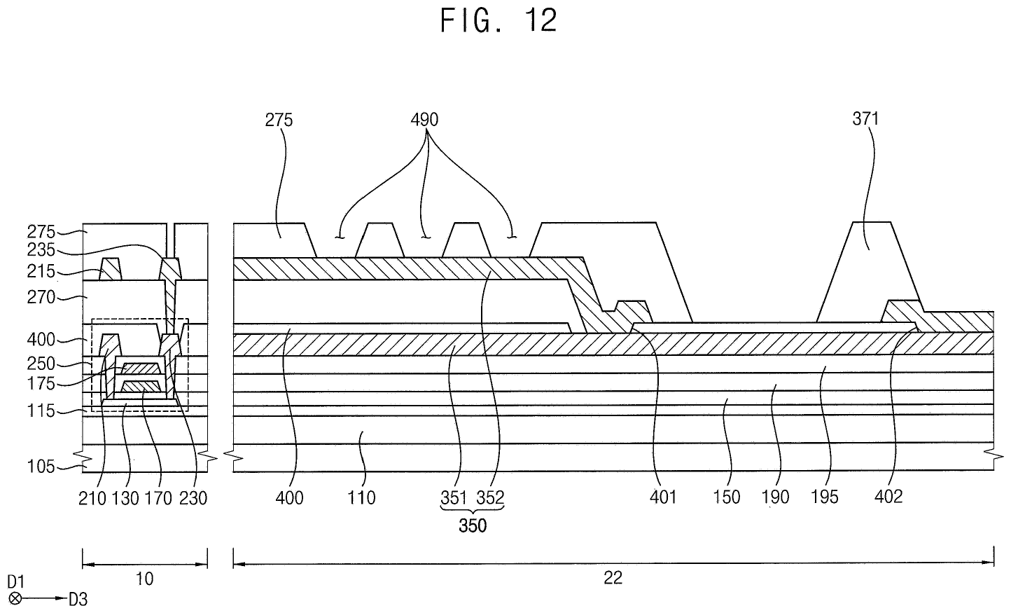

Referring to FIG. 12, a second planarization layer 275 may be formed on the wire pattern 215, the connection electrode 235, the second sub-power supply wire 352, and the first planarization layer 270. The second planarization layer 275 may cover the wire pattern 215 and the connection electrode 235 in the display region 10 on the first planarization layer 270 while extending in the third direction D3 so as to cover the second sub-power supply wire 352 in the peripheral region 20. In exemplary embodiments, the second planarization layer 275 may have openings 490 for exposing the top surface of the second sub-power supply wire 352 in the second peripheral region 22. The openings 490 may be formed in a portion where the first power supply wire 350 and the connection pattern 295 are overlapped with each other in the third peripheral region 23. Moreover, the second planarization layer 275 may cover the end of the second sub-power supply wire 352 formed in the first opening 401 in the second peripheral region 22, and may have a contact hole for exposing the connection electrode 235 in the display region 10.

The second planarization layer 275 may have a relatively thick thickness to sufficiently cover the wire pattern 215, the connection electrode 235, and the second sub-power supply wire 352, and in this case, the second planarization layer 275 may have a substantially flat top surface. In order to implement such a flat top surface of the second planarization layer 275, the planarization process may be additionally performed on the second planarization layer 275. As an example, the second planarization layer 275 may cover the wire pattern 215, the connection electrode 235, and the second sub-power supply wire 352, and may be formed along the profiles of the wire pattern 215, the connection electrode 235, and the second sub-power supply wire 352 with a uniform thickness. The second planarization layer 275 may be formed using an organic material.

A first blocking pattern 371 may be formed in the peripheral region 20 on the protective insulating layer 400 and the first sub-power supply wire 351. The first blocking pattern 371 may be spaced apart from the second planarization layer 275 in the third direction D3, and may cover a first end of the second sub-power supply wire 352 formed in the second opening 402. For example, the first blocking pattern 371 may be formed along the profile of the outer peripheral edge of the display region 10. In other words, the first blocking pattern 371 may surround the display region 10 in the first peripheral region 21, the second peripheral region 22, and the third peripheral region 23. In exemplary embodiments, the second planarization layer 275 and the first blocking pattern 371 may be formed simultaneously using an identical material.

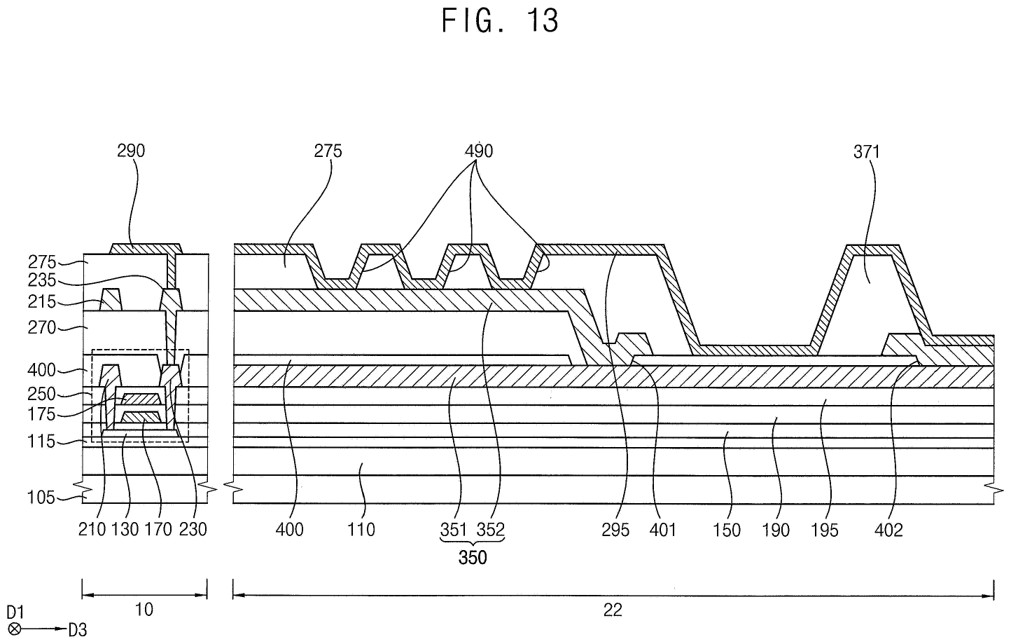

Referring to FIG. 13, a lower electrode 290 may be formed in the display region 10 on the second planarization layer 275. The lower electrode 290 may be connected to the connection electrode 235 through the contact hole formed by removing a part of the second planarization layer 275. The lower electrode 290 may be formed using a metal, an alloy of a metal, metal nitride, conductive metal oxide, a transparent conductive material, etc. These may be used alone or in combination with each other. In exemplary embodiments, the lower electrode 290 may have a multilayer structure including multiple layers.

A connection pattern 295 may be formed in the peripheral region 20 on the second planarization layer 275, the protective insulating layer 400, the first blocking pattern 371, and the second sub-power supply wire 352. The connection pattern 295 may be formed on the second planarization layer 275, the inner sides of the openings 490 of the second planarization layer 275, the protective insulating layer 400 disposed between the second planarization layer 275 and the first blocking pattern 371, the first blocking pattern 371, and the second sub-power supply wire 352 formed in the second opening 402, and may extend in the third direction D3. In other words, the connection pattern 295 may be formed along the profiles of the second planarization layer 275, the protective insulating layer 400, the first blocking pattern 371, and the second sub-power supply wire 352. The connection pattern 295 may be formed using a metal, an alloy of a metal, metal nitride, conductive metal oxide, a transparent conductive material, etc. These may be used alone or in combination with each other. In exemplary embodiments, the connection pattern 295 may have a multilayer structure including multiple layers, and the lower electrode 290 and the connection pattern 295 may be formed simultaneously using an identical material.

For example, after a preliminary third electrode layer is formed on the second planarization layer 275, the second sub-power supply wire 352, and the protective insulating layer 400, the preliminary third electrode layer may be partially etched to simultaneously form the lower electrode 290 and the connection pattern 295.

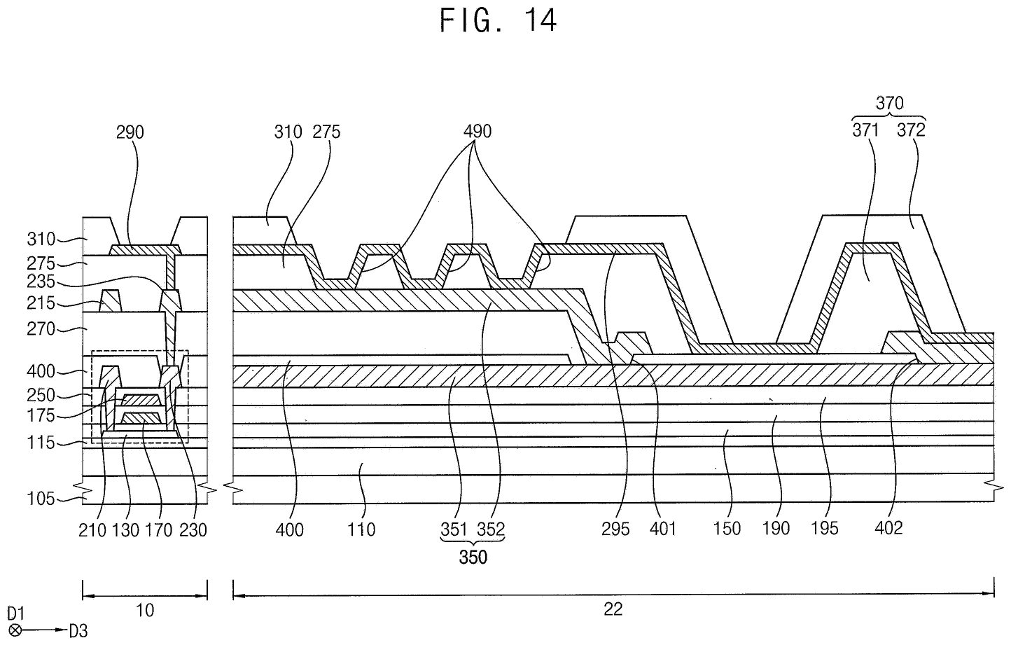

Referring to FIG. 14, a pixel defining layer 310 may be formed in the display region 10 and the second peripheral region 22 on the second planarization layer 275. The pixel defining layer 310 may expose a part of the lower electrode 290 in the display region 10 while extending in the third direction D3, and may be formed on the connection pattern 295 while exposing the connection pattern 295 formed in the openings 490 in the second peripheral region 22. The pixel defining layer 310 may be formed using an organic material.

A second blocking pattern 372 may be formed in the peripheral region 20 on the connection pattern 295. The second blocking pattern 372 may be spaced apart from the pixel defining layer 310 in the third direction D3, and may cover the connection pattern 295 formed on the first blocking pattern 371. For example, the second blocking pattern 372 may extend in the first direction D1, and may be formed along the profile of the outer peripheral edge of the display region 10. In other words, the second blocking pattern 372 may surround the display region 10 in the first peripheral region 21, the second peripheral region 22, and the third peripheral region 23. The second blocking pattern 372 may be formed using an organic material. The pixel defining layer 310 and the second blocking pattern 372 may be formed simultaneously using an identical material.

Accordingly, a blocking structure 370 including the first blocking pattern 371 and the second blocking pattern 372 may be formed.

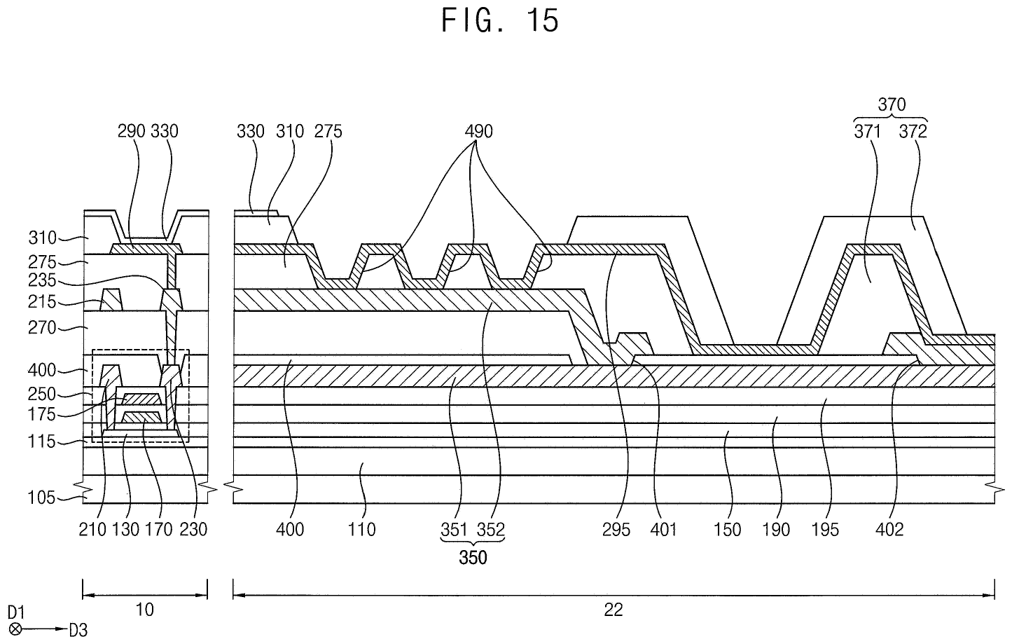

Referring to FIGS. 15 and 16, a light emitting layer 330 may be formed in the display region 10 and a part of the peripheral region 20 on the substrate 110. For example, the light emitting layer 330 may be formed on the pixel defining layer 310 and the lower electrode 290 in the display region 10 while extending in the third direction D3, and may be formed on a part of the pixel defining layer 310 in the peripheral region 20. In other words, the light emitting layer 330 may be formed along the profiles of the pixel defining layer 310 and the lower electrode 290. In exemplary embodiments, the light emitting layer 330 might not be overlapped with the openings 490. The light emitting layer 330 may have a multilayer structure including an EML, an HIL, an HTL, an ETL, an EIL, etc. The EML of the light emitting layer 330 may be formed using at least one of the light emitting materials for emitting the different color lights according to the sub-pixels. As another example, the EML of the light emitting layer 330 may be formed by laminating light emitting materials for emitting the different color lights such as the red light, the green light, or the blue light to emit the white light as a whole. In this case, the color filter may be formed on the light emitting layer 330 which is formed on the lower electrode 290. The color filter may include at least one of the red color filter, the green color filter, and the blue color filter. As another example, the color filter may include the yellow color filter, the cyan color filter, and the magenta color filter. The color filter may be formed using a photosensitive resin or color photoresist.

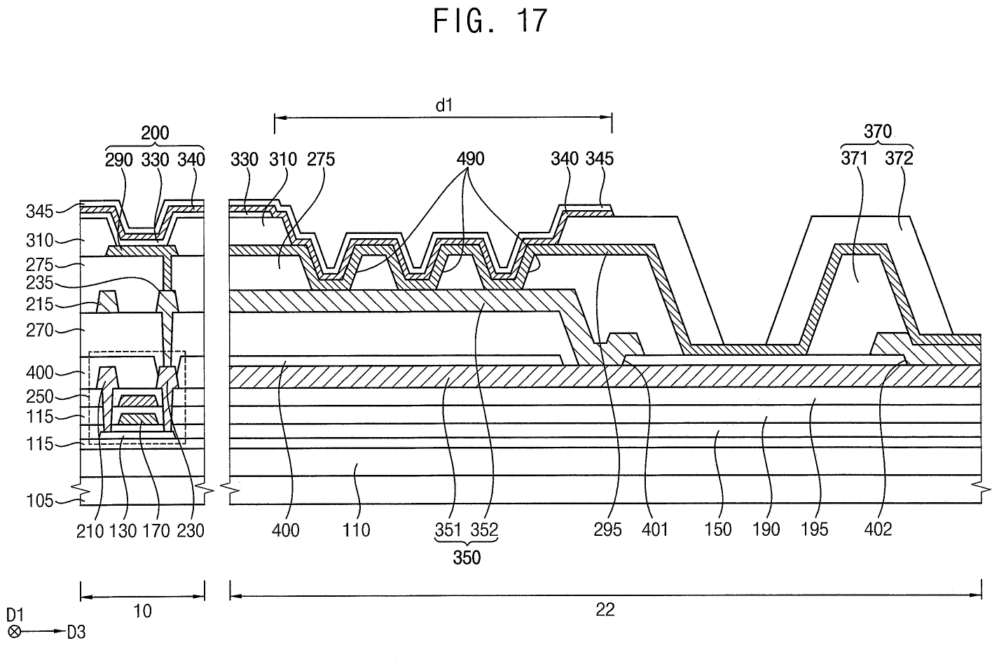

Referring to FIGS. 17 and 18, an upper electrode 340 may be formed in the display region 10 and a part of the peripheral region 20 on the substrate 110. For example, the upper electrode 340 may be formed on the light emitting layer 330 in the display region 10 while extending in the third direction D3, and may be formed on the light emitting layer 330, a part of the pixel defining layer 310, the connection pattern 295 formed in the openings 490 in the peripheral region 20. In other words, the upper electrode 340 may be formed along the profiles of the light emitting layer 330, the pixel defining layer 310, and the connection pattern 295. In exemplary embodiments, the upper electrode 340 may make direct contact with the connection pattern 295 formed in the openings 490. The upper electrode 340 may be formed using a metal, an alloy of a metal, metal nitride, conductive metal oxide, a transparent conductive material, etc. These may be used alone or in combination with each other. In exemplary embodiments, the upper electrode 340 may have a multilayer structure including multiple layers.

Accordingly, a sub-pixel structure 200 including the lower electrode 290, the light emitting layer 330, and the upper electrode 340 may be formed, as described.

As shown in FIGS. 17 and 18, the upper electrode 340 may protrude from the light emitting layer 330 in the third direction D3 (e.g., a direction from the display region 10 to the peripheral region 20) by a first distance d1. In other words, an area of the upper electrode 340 may be greater than an area of the light emitting layer 330. The display region 10 may have a rectangular shape with curved corners when viewed from the top, and the light emitting layer 330 and the upper electrode 340 may also have a rectangular shape with curved corners when viewed from the top.

Due to the rectangular shape with the curved corners when viewed from the top, distances by which the upper electrode 340 protrudes from the light emitting layer 330 in the third direction D3 may be different from each other in the first peripheral region 21, the second peripheral region 22, and the third peripheral region 23. For example, a second distance d2 by which the upper electrode 340 protrudes from the light emitting layer 330 in a region A may be relatively less than a distance by which the upper electrode protrudes from the light emitting layer 330 in other regions. In this case, since the second distance d2 is too small in the region A, it may be difficult to form an opening for exposing the second sub-power supply wire 352 in the second planarization layer 275. Therefore, the openings 490 are not formed in the second planarization layer 275 in the region A.

Referring again to FIG. 17, a capping layer 345 may be formed in the display region 10 and a part of the second peripheral region 22 on the substrate 110. For example, the capping layer 345 may be formed on the upper electrode 340 in the display region 10 while extending in the third direction D3, and may be formed on the upper electrode 340 in the peripheral region 20. In other words, the capping layer 345 may be formed along the profile of the upper electrode 340 in the display region 10 and the peripheral region 20. In exemplary embodiments, the capping layer 345 may be overlapped with the upper electrode 340 in the peripheral region 20. The capping layer 345 may be formed using a triamine derivative, an arylenediamine derivative, 4,4′-N,N′-dicarbazole-biphenyl CBP, Alq3, etc.

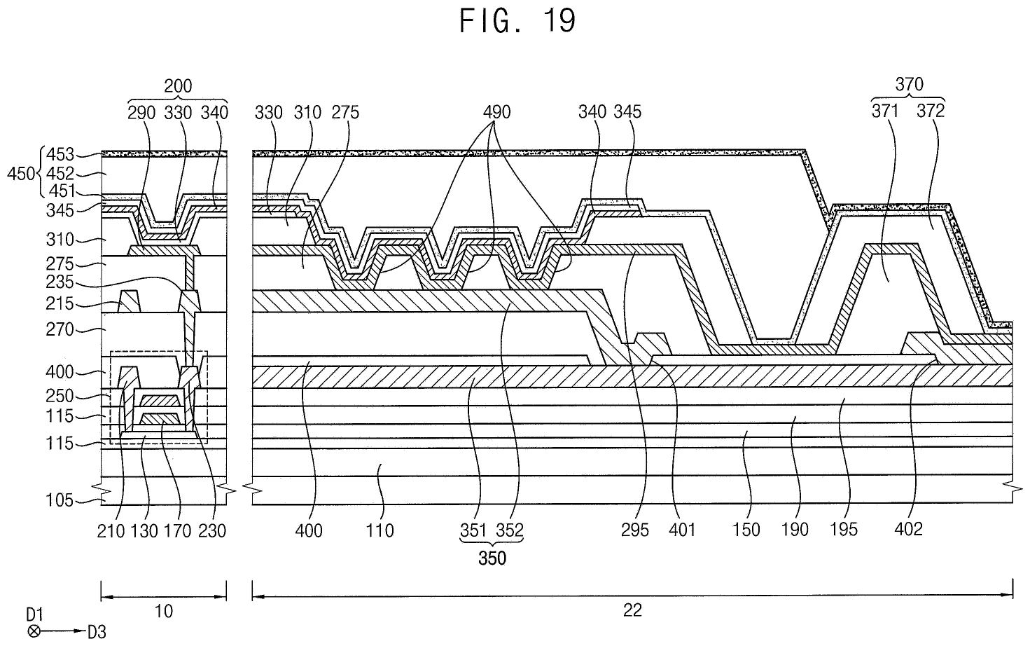

Referring to FIG. 19, a first thin film encapsulation layer 451 may be formed in the display region 10 and the peripheral region 20 on the substrate 110. For example, the first thin film encapsulation layer 451 may be formed on the capping layer 345 in the display region 10 while extending in the third direction D3, and may be formed on the capping layer 345, the pixel defining layer 310, the blocking structure 370, and the connection pattern 295 in the peripheral region 20. In other words, the first thin film encapsulation layer 451 may be formed along the profiles of the capping layer 345, the pixel defining layer 310, the blocking structure 370, and the connection pattern 295. In exemplary embodiments, the first thin film encapsulation layer 451 may make direct contact with the capping layer 345 in the openings 490, and may make direct contact with the connection pattern 295 in a portion disposed between the pixel defining layer 310 and the blocking structure 370 in the second peripheral region 22. The first thin film encapsulation layer 451 may be formed using flexible inorganic materials.

A second thin film encapsulation layer 452 may be formed in the display region 10 and a part of the peripheral region 20 on the first thin film encapsulation layer 451. The second thin film encapsulation layer 452 may be overlapped with a part of the side wall of the blocking structure 370. As another example, the second thin film encapsulation layer 452 might not be overlapped with the blocking structure 370, or may cover the blocking structure 370 while extending in the third direction D3. The second thin film encapsulation layer 452 may be formed using flexible organic materials.

A third thin film encapsulation layer 453 may be formed on the second thin film encapsulation layer 452 and the first thin film encapsulation layer 451. The third thin film encapsulation layer 453 may cover the second thin film encapsulation layer 452 in the display region 10 while being formed along the profile of the second thin film encapsulation layer 452 with a uniform thickness, and may extend to the peripheral region 20. The third thin film encapsulation layer 453 may be formed along the profiles of the first thin film encapsulation layer 451 and a part of the second thin film encapsulation layer 452 in the peripheral region 20. The third thin film encapsulation layer 453 may be formed using flexible inorganic materials.

Accordingly, a thin film encapsulation structure 450 including the first thin film encapsulation layer 451, the second thin film encapsulation layer 452, and the third thin film encapsulation layer 453 may be formed. As another example, the thin film encapsulation structure 450 may have a five-layer structure formed by laminating first to fifth thin film encapsulation layers or a seven-layer structure formed by laminating first to seventh thin film encapsulation layers.

After the thin film encapsulation structure 450 is formed, the glass substrate 105 may be removed from the substrate 110. Accordingly, the OLED display device 100 shown in FIG. 6A may be manufactured.

The invention may be applied to various display devices including an OLED display device. For example, the invention may be applied to vehicle-display device, a ship-display device, an aircraft-display device, portable communication devices, display devices for display or for information transfer, a medical-display device, etc.

While the invention has been illustrated and described with reference to the embodiments thereof, it will be apparent to those of ordinary skill in the art that various changes in form and detail may be formed thereto without departing from the spirit and scope of the invention.

What is claimed is:

1. An organic light emitting diode (OLED) display device comprising:
a substrate having a display region, a peripheral region surrounding the display region, and a pad region disposed in a side of the peripheral region, the peripheral region including a first peripheral region, a second peripheral region, and a third peripheral region;
a light emitting layer disposed in the display region;
a first power supply wire disposed in the second peripheral region, the third peripheral region, and a part of the first peripheral region;
a second power supply wire disposed in the display region, the first peripheral region, and the third peripheral region, the second power supply wire being disposed outside of the second peripheral region;
a connection pattern disposed to overlap with the first power supply wire in the second peripheral region and the third peripheral region, the connection pattern being electrically connected to the first power supply wire; and
an upper electrode disposed in the display region and a part of the peripheral region over the connection pattern and the light emitting layer, the upper electrode being overlapped with the first power supply wire and the connection pattern, the upper electrode being electrically connected to the connection pattern.

2. The OLED display device of claim 1, further comprising:
pad electrodes disposed in a first part of the pad region,
wherein
the first peripheral region is disposed adjacent to the first part of the pad region, and
the second peripheral region is disposed at sides of the first peripheral region, and adjacent to a second part of the pad region where no pad electrode is disposed.

3. The OLED display device of claim 2, wherein the first power supply wire is electrically connected to the pad electrodes.

4. The OLED display device of claim 3, wherein the first power supply wire is electrically connected with at least two of the pad electrodes, and the second power supply wire is electrically connected with at least one of the pad electrodes, the at least one of the pad electrodes connected with the second power supply wire being disposed inward of the at least two of the pad electrodes connected with the first power supply wire.

5. The OLED display device of claim 1, wherein the connection pattern is disposed outside of the first peripheral region.

6. The OLED display device of claim 1, wherein a low power supply voltage is applied to the first power supply wire, and a high power supply voltage is applied to the second power supply wire.

7. The OLED display device of claim 1, wherein the second power supply wire includes:
a first portion disposed in the first peripheral region;
a second portion disposed in the display region, and having a lattice shape; and
a third portion disposed in a part of the third peripheral region to surround the second portion, and
the first, second, and third portions of the second power supply wire are formed integrally with each other.

8. The OLED display device of claim 7, wherein the first and second portions of the second power supply wire are connected to each other in a part of the first peripheral region that is adjacent to a boundary between the display region and the peripheral region, and
the second and third portions of the second power supply wire are connected to each other in a part of the third peripheral region that is adjacent to the boundary between the display region and the peripheral region.

9. The OLED display device of claim 7, wherein the third portion of the second power supply wire is spaced apart from an inner side of the first power supply wire in the third peripheral region.

10. The OLED display device of claim 7, wherein the third portion of the second power supply wire is disposed outside of the second peripheral region.

11. The OLED display device of claim 1, wherein the display region has a rectangular shape with curved corners when viewed in a plan view, and
the curved corners of the display region include:
first curved corners disposed adjacent to the pad region; and
second curved corners facing the first curved corners.

12. The OLED display device of claim 11, wherein the first curved corners are disposed adjacent to the second peripheral region, and the second curved corners are disposed adjacent to the third peripheral region.

13. The OLED display device of claim 1, wherein the first power supply wire has a first width in the second peripheral region, and has a second width, which is less than the first width, in the third peripheral region.

14. The OLED display device of claim 13, wherein the connection pattern has a width corresponding to each the first width and the second width of the first power supply wire.

15. The OLED display device of claim 1, further comprising:
a protective insulating layer disposed in the display region and the peripheral region and between the substrate and the light emitting layer, the protective insulating layer having an opening in the second peripheral region;
a first planarization layer disposed in the display region and a part of the peripheral region, and on the protective insulating layer to expose the opening of the protective insulating layer; and
a second planarization layer disposed in the display region and a part of the peripheral region, and on the first planarization layer, the second planarization layer having an opening for exposing the first power supply wire in the second peripheral region.

16. The OLED display device of claim 15, wherein the light emitting layer extends from the display region to the peripheral region, and the light emitting layer is disposed in the peripheral region to not overlap with the opening of the second planarization layer.

17. The OLED display device of claim 15, further comprising:
a lower electrode disposed in the display region, and on the second planarization layer,
wherein the upper electrode is disposed on the lower electrode, and to extend from the display region to the peripheral region.

18. The OLED display device of claim 17, wherein the upper electrode directly contacts the connection pattern in the second peripheral region.

19. The OLED display device of claim 18, wherein the lower electrode and the connection pattern are disposed on a same layer.

20. The OLED display device of claim 15, wherein the first power supply wire includes:
a first sub-power supply wire disposed between the substrate and the protective insulating layer, the first sub-power supply wire being exposed by the opening of the protective insulating layer; and
a second sub-power supply wire disposed between the first planarization layer and the second planarization layer, the second sub-power supply wire directly contacting the first sub-power supply wire through the opening of the protective insulating layer, the second sub-power supply wire being exposed by the opening of the second planarization layer.

21. The organic light emitting diode display device of claim 20, wherein the connection pattern directly contacts the second sub-power supply wire through the opening of the second planarization layer.

22. The organic light emitting diode display device of claim 20, further comprising:
a semiconductor element disposed in the display region, and between the substrate and the protective insulating layer; and
a wire pattern and a connection electrode disposed in the display region, and between the first planarization layer and the second planarization layer.

23. The organic light emitting diode display device of claim 22, wherein the wire pattern, the connection electrode, and the second sub-power supply wire are disposed on a same layer.

24. The organic light emitting diode display device of claim 22, wherein the semiconductor elements includes:
an active layer disposed in the display region;
a gate insulating layer disposed on the active layer;
a gate electrode disposed on the gate insulating layer;
an insulating interlayer disposed on the gate electrode; and
source and drain electrodes disposed on the insulating interlayer.

25. The organic light emitting diode display device of claim 24, wherein the source and drain electrodes and the first sub-power supply wire are disposed on a same layer.
